(19) United States
(12) Patent Application Publication
(10) Pub. No.: US 2026/0161865 A1
(43) Pub. Date: Jun. 11, 2026

(54) ORCHESTRATED ANALYSIS AND OPTIMIZATION OF HARDWARE DESIGNS BASED ON LOGIC CONE ANALYSIS

(71) Applicant: Microsoft Technology Licensing, LLC, Redmond, WA (US)

(72) Inventors: Aditya Chandrasekar RAMACHANDRAN, Fremont, CA (US); Charles STRATAKOS, Saratoga, CA (US)

(73) Assignee: Microsoft Technology Licensing, LLC, Redmond, WA (US)

(21) Appl. No.: 18/973,826

(22) Filed: Dec. 9, 2024

(51) Int. Cl. G06F 30/33; G06F 30/337

(52) U.S. Cl. CPC G06F 30/33; G06F 30/337

(57) ABSTRACT

Systems and methods are provided for implementing orchestrated analysis and optimization of hardware designs based on logic cone analysis. An orchestrator receives, from an electronic design automation (“EDA”) tool, initial results of optimization and validation of chip designs, indicating first cones of logic undergoing changes beyond a threshold value and second cones of logic undergoing changes below the threshold value, over multiple parameter values (e.g., operating frequencies, power draw, or area). The orchestrator instructs the EDA tool to repeat optimization and validation, while re-allocating a portion of runtime, speed, or delay per cone of logic from the second to the first cones of logic. The orchestrator receives results corresponding to measured metrics for each cone of logic, determines, for each of the first cones of logic, whether that cone of logic undergoes changes beyond the threshold value over the multiple parameter values, and sends updated results to a user device.

### BACKGROUND

One of the most important factors that determines the market competitiveness of an integrated circuit (“IC”) chip design is its performance to price ratio. Existing tools produce reports that provide information regarding performance and cost. Such tools, however, only report performance and cost metrics at the design level, and only by measuring the current implementation. It is with respect to this general technical environment to which aspects of the present disclosure are directed. In addition, although relatively specific problems have been discussed, it should be understood that the examples should not be limited to solving the specific problems identified in the background.

### SUMMARY

This summary is provided to introduce a selection of concepts in a simplified form that are further described below in the detailed description section. This summary is not intended to identify key features or essential features of the claimed subject matter, nor is it intended as an aid in determining the scope of the claimed subject matter.

The currently disclosed technology, among other things, provides for implementing orchestrated analysis and optimization of hardware designs based on logic cone analysis. In examples, an orchestrator receives initial results of optimization and validation of designs of an IC chip from an electronic design automation (“EDA”) tool. The initial results indicate first cones of logic that undergo changes beyond a threshold value over a range of different operating frequencies and indicate second cones of logic that undergo changes below the threshold value over the range of different operating frequencies. The orchestrator instructs the EDA tool to repeat optimization and validation of the designs of the IC chip over one of the range of different operating frequencies per optimization and validation session, while re-allocating a portion of runtime, speed, or delay per cone of logic from the second cones of logic to the first cones of logic during each optimization and validation session. The orchestrator receives results corresponding to measured metrics for each cone of logic, and determines, for each of the first cones of logic, whether that cone of logic undergoes changes beyond or below the threshold value over the range of different operating frequencies. The orchestrator sends updated results of the optimization and validation of the designs of the IC chip to a user device associated with an IC chip designer, based on the received results and the determination.

The details of one or more aspects are set forth in the accompanying drawings and description below. Other features and advantages will be apparent from a reading of the following detailed description and a review of the associated drawings. It is to be understood that the following detailed description is explanatory only and is not restrictive of the invention as claimed.

### BRIEF DESCRIPTION OF THE DRAWINGS

A further understanding of the nature and advantages of particular embodiments may be realized by reference to the remaining portions of the specification and the drawings, which are incorporated in and constitute a part of this disclosure.

FIG. 1 depicts an example system for implementing orchestrated analysis and optimization of hardware designs based on logic cone analysis.

FIGS. 2A and 2B depict example representations of relationships between cones of logic and registers that may be used when implementing orchestrated analysis and optimization of hardware designs based on logic cone analysis.

FIGS. 2C and 2D depict example representations of cones of logic corresponding to initial results and updated results across different operating frequencies when implementing orchestrated analysis and optimization of hardware designs based on logic cone analysis.

FIGS. 3A-3C depict various example results when implementing orchestrated analysis and optimization of hardware designs based on logic cone analysis.

FIGS. 4A and 4B depict an example method for implementing orchestrated analysis and optimization of hardware designs based on logic cone analysis.

FIGS. 5A-5C depict another example method for implementing orchestrated analysis and optimization of hardware designs based on logic cone analysis.

FIGS. 6A-6C depict yet another example method for implementing orchestrated analysis and optimization of hardware designs based on logic cone analysis.

FIG. 7 depicts a block diagram illustrating example physical components of a computing device with which aspects of the technology may be practiced.

### DETAILED DESCRIPTION OF CERTAIN EMBODIMENTS

As briefly discussed above, one of the most important factors that determines the market competitiveness of an IC chip design is its performance to price ratio. A chip design team tasked with developing the most competitive chip will therefore seek to maximize performance and minimize cost, where cost is largely the IC chip's power consumption and area (or size). Absent any other constraints (e.g., time, effort, and/or quality), IC chip design teams desire the highest performance in terms of operating frequency, the lowest power, and the lowest area. However, the three are not achievable together as they are competing metrics. Typically, increased performance comes at the cost in terms of increased area, increased power, or both.

Since performance and cost are competing objectives, co-optimizing them implies a tradeoff, and such tradeoffs are best done through a sensitivity analysis. However, the performance versus cost sensitivity is not uniform across an IC chip design. Some cones of logic may show that a performance increase of 20% causes a cost increase of 30%. Other cones of logic may show that a performance increase of 20% can be achieved with just a 1% cost increase. Knowledge of the performance versus cost sensitivity of each logic cone, combined with the understanding of the relationships between logic cones, allows for precise, high impact actions and/or opportunities for action to be identified.

For many chip designs, EDA tools are used to generate a physical representation (in terms of transistor and wire layout) of much of the chip design. The EDA tools take as inputs a software description of the function and/or behavior of the chip design (e.g., a register transfer level (“RTL”) design abstraction) and various constraints that need to be satisfied (e.g., the desired or target operating frequency(ies)). The EDA tools use complex optimization and transformation algorithms in an attempt to meet the desired performance, to satisfy all other requirements, and to keep cost to a minimum. The resulting physical representation is strongly dependent on the inputs—a small change in the inputs can sometimes have a significant impact on the output. Much of the chip design team's effort is spent manipulating the inputs to the EDA tools to achieve the best performance at least cost.

Given the importance of performance and cost, existing EDA tools produce many reports to give chip designers information regarding performance and cost. However, such reports typically only include performance and cost metrics at the design level, and only by measuring the current implementation. While useful to identify performance shortfalls, current reporting capabilities are inadequate to identify the best opportunities to improve cost.

The present technology provides for implementing orchestrated analysis and optimization of hardware designs based on logic cone analysis. The present technology enables reporting of metrics on a much more granular basis (e.g., on a per logic cone basis), and with sensitivities derived from implementing the IC chip design across a range of performance targets (e.g., over a range of operating frequencies). With the cost versus operating frequency sensitivity (i.e., the incremental cost for a unit increase in operating frequency) for each logic cone in the IC chip design, the present technology provides for meaningful and efficient improvement to the IC chip design in two ways:
(1) The cost of an IC chip design is cumulative across the entire IC chip design. To reduce cost, logic cones may be redesigned with high cost versus operating frequency sensitivity to reduce cost at the desired operating frequency; and/or
(2) The operating frequency of an IC chip design is typically limited by a small subset of its cones of logic. Due to multiple solutions being available to improve the operating frequency, where each solution may impact different cones of logic, a solution may be selected that achieves the desired operating frequency at least cost.

Although solutions exist that execute a chip design at multiple performance points and that report metrics for area, power, and operating frequency, no existing solutions perform the following tasks that are enabled by the present technology:
(a) calculate metrics on a per logic cone level at a single frequency;
(b) generate per logic cone area versus operating frequency and/or power versus operating frequency sensitivities;
(c) provide insights or recommendations regarding how, where, and/or which logic cone to act upon to efficiently reduce cost;
(d) provide insights or recommendations about how, where, and/or which logic cone to act upon to improve frequency at least cost; and/or
(e) act on the insights to automatically improve area, power, and/or frequency.

The present technology also provides for the following aspects:
(I) calculates or causes the EDA tool to calculate area and power, per cone of logic, per operating frequency point;
(II) generates curve-fitted graphs of area versus operating frequency and/or power versus operating frequency from the generated data points;
(III) generates a report(s) and/or summary(ies) of cones of logic with high cost performance ratios at chosen operating frequency steps;
(IV) generates a report(s) and/or summary(ies) of cones of logic with high cost performance factors (e.g., exponential or linear factors) from fitted curves; and/or
(V) performs automatic optimization of the IC chip designs to current or new performance points by using the per logic cone cost performance ratio to determine least cost solutions.

Various modifications and additions can be made to the embodiments discussed herein without departing from the scope of the disclosed techniques. For example, while the embodiments described above refer to particular features, the scope of the disclosed techniques also includes embodiments having different combinations of features and embodiments that do not include all of the above-described features.

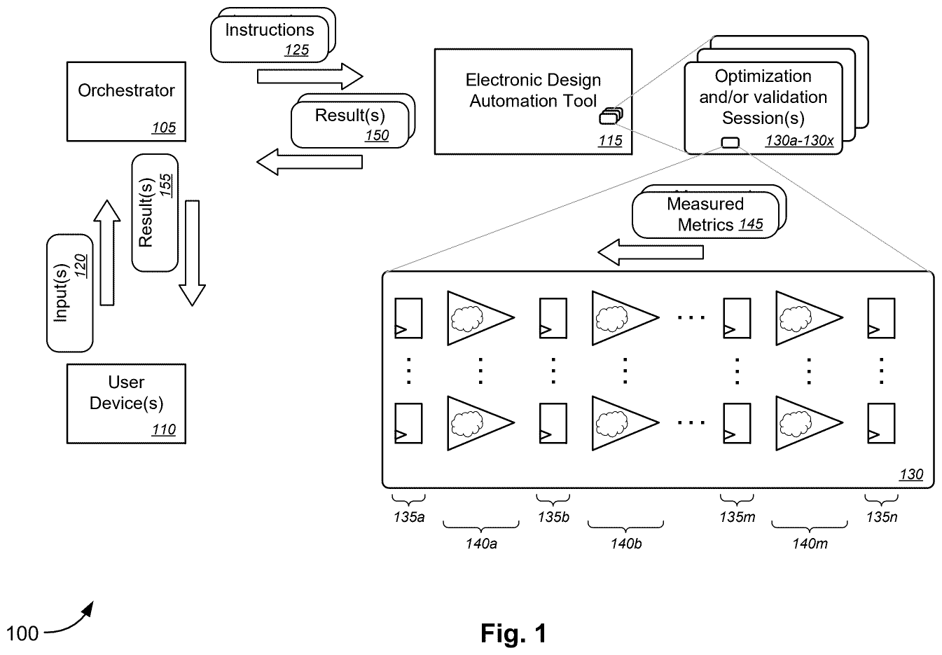

Turning to the embodiments as illustrated by the drawings, FIGS. 1-7 illustrate some of the features of methods, systems, and apparatuses for implementing orchestrated analysis and optimization of hardware designs based on logic cone analysis, as referred to above. The methods, systems, and apparatuses illustrated by FIGS. 1-7 refer to examples of different embodiments that include various components and steps, which can be considered alternatives or which can be used in conjunction with one another in the various embodiments. The description of the illustrated methods, systems, and apparatuses shown in FIGS. 1-7 is provided for purposes of illustration and should not be considered to limit the scope of the different embodiments.

FIG. 1 depicts an example system 100 for implementing orchestrated analysis and optimization of hardware designs based on logic cone analysis. System 100 includes orchestrator 105, a user device(s) 110, and electronic design automation (“EDA”) tool 115. In response to receiving one or more inputs 120 from the user device(s) 110, the orchestrator 105 sends instructions 125 to the EDA tool 115. In some examples, the one or more inputs 120 include a request to optimize and validate of designs of an integrated circuit (“IC”) chip. In some cases, the request includes parameters including one or more of operating frequencies, power draw parameters (e.g., minimum power draws, maximum power draws, and/or power draw ranges), and/or IC chip area parameters (e.g., minimum area, maximum area, and/or area ranges). In examples, the instructions 125 include at least one of instructions to optimize and validate designs of the IC chip that are constrained (or bounded) by one or more values of a sweep variable, instructions to optimize and validate designs of the IC chip that are constrained by an operating frequency over a default runtime, speed, or delay for each cone of logic, instructions to optimize and validate designs of the IC chip that are constrained by two or more operating frequencies over the default runtime, speed, or delay for each cone of logic, and/or instructions to re-allocate a portion of runtime, speed, or delay per cone of logic from some cones of logic to other first cones of logic. As used herein, runtime refers to how long the EDA tool 115 takes to build the design(s) of the IC chip, while speed or delay refers to how long the circuit takes to complete one atomic operation. Based on the instructions 125, the EDA tool 115 runs a plurality of sequential optimization and/or validation sessions 130a-130x (collectively, “optimization and/or validation sessions 130”). As used herein, a “sweep variable” (also referred to as a “sweep parameter”) refers to a variable that is changed from one value during one iteration (in this case, an optimization and/or validation session) to another during another iteration, and so on, in some cases, either increasing in value or decreasing in value from one iteration to the next and the next after that. In various examples, the operating frequency is the sweep variable that is changed from one iteration to the next, and so on. Other variables, however, may be selected to be sweep variable. In general, the various embodiments provide for any directed or non-uniform allocation of resources (e.g., tool runtime, circuit delay, circuit area, or circuit power) based on sensitivity analysis per cone of logic to improve another metric of interest, which are described below. In an example, for operating frequency or allowed delay as an independent variable and power draw as a measured variable, the orchestrator finds a way to re-allocate delay (e.g., using clock cycle expansion) across cones of logic to reduce the total power draw. In another example, for operating frequency or allowed delay as an independent variable and area as a measured variable, the orchestrator finds a way to re-allocate delay (e.g., using clock cycle expansion) across cones of logic to reduce the total area. In yet another example, for total area as an independent variable and power draw as a measured variable, the orchestrator finds a way to re-allocate area across cones of logic to reduce the total power draw. And so on.

In each optimization and/or validation session 130, designs of the IC chip are optimized and/or validated by the EDA tool 115. The designs of the IC chip include a plurality of registers 135a-135n (collectively, “registers 135”), and a plurality of cones of logic 140a-140m (collectively, “cones of logic 140”). Herein, m, n, and x are non-negative integer numbers that may be either all the same as each other, all different from each other, or some combination of same and different (e.g., one set of two or more having the same values with the others having different values, a plurality of sets of two or more having the same value with the others having different values). Each cone of logic 140 represents a series of different design implementations of a logical operation that is sequentially optimized and/or validated, by the EDA tool, in succeeding optimization and/or validation sessions among the plurality of sequential optimization and/or validation sessions 130 to identify an optimal configuration of logical components for one of a plurality of sets of logical components configured to operate at one of the plurality of operating frequencies or one of the sweep variables for each of the plurality of sequential optimization and/or validation sessions 130. For each optimization and/or validation session among the plurality of sequential optimization and/or validation sessions 130, the EDA tool 115 is caused to repeat an optimization and validation cycle for each cone of logic, until the default runtime, speed, or delay for that cone of logic has elapsed, the optimization and validation cycle including: (a) optimizing and/or validating a design implementation of the logical operation for that cone of logic; (b) obtaining an intermediate value for each of one or more measured metrics for the design implementation; and (c) changing to another design implementation of the logical operation for that cone of logic.

In examples, each set of logical components that corresponds to a logical operation receives at least one input value that is stored in a corresponding at least one register among the plurality of registers 135 and that outputs at least one output value to a corresponding at least one other register among the plurality of registers 135. In some examples, the plurality of registers 135 includes at least one input register (e.g., register(s) 135a), at least one output register (e.g., register(s) 135n), and a plurality of intermediate registers (e.g., register(s) 135b-135m). In some cases, each intermediate register receives one or more input values stored in one or more first registers among the plurality of registers and outputs one or more output values for storage in one or more second registers among the plurality of registers. In some instances, the one or more first registers include one or more of the at least one input register or at least one first intermediate register among the plurality of intermediate registers, while the one or more second registers include one or more of the at least one output register or at least one second intermediate register among the plurality of intermediate registers. The EDA tool 115 outputs one or more measured metrics 145 to the orchestrator 105, in some cases, as part of result(s) 150. In examples, the orchestrator 105 returns result(s) 155 to user device(s) 110. In some instances, result(s) 150 and result(s) 155 are the same. In other cases, result(s) 155 is different from, but based on, the result(s) 150.

In an example, the sweep variable is an operating frequency of the IC chip, and the one or more measured metrics 145, as measured for each cone of logic, include one or more of an area of that cone of logic, a power draw for that cone of logic, or a runtime of the EDA tool when optimizing and/or validating designs for that cone of logic. In another example, the sweep variable is a total area of the IC chip, and the one or more measured metrics 145, as measured for each cone of logic, include one or more of an inverse of an operating frequency for that cone of logic, a power draw for that cone of logic, or a runtime of the EDA tool when optimizing and/or validating designs for that cone of logic. In yet another example, the sweep variable is a total power draw of the IC chip, and the one or more measured metrics 145, as measured for each cone of logic, include one or more of an area of that cone of logic, an inverse of an operating frequency for that cone of logic, or a runtime of the EDA tool when optimizing and/or validating designs for that cone of logic. In still another example, the sweep variable is a total runtime of the EDA tool when optimizing and/or validating the designs of the IC chip, and the one or more measured metrics 145, as measured for each cone of logic, include one or more of an area of that cone of logic, a power draw for that cone of logic, or an inverse of an operating frequency for that cone of logic.

In examples, the result(s) 150 received by the orchestrator 105 include initial results of optimization and validation of designs of the IC chip, which indicate that one or more first cones of logic among the plurality of cones of logic 140 each undergoes a change in terms of one or more measured metrics 145 for that cone of logic that exceeds a threshold value (e.g., a change of 30, 40, 50, 60, 70, 80, 90%, or greater) when configured to operate at a first operating frequency compared with when configured to operate at a second operating frequency among the plurality of operating frequencies. The initial results further indicate that one or more second cones of logic among the plurality of cones of logic each undergoes a change in terms of the one or more measured metrics for that cone of logic that falls below the threshold value. In response to receiving the initial results, the orchestrator 105 sends instructions 125 including instructions to optimize and validate designs of the IC chip that are constrained by the sweep variable, and instructions to re-allocate a portion of runtime, speed, or delay per cone of logic from the one or more second cones of logic to the one or more first cones of logic during each of the plurality of sequential optimization and/or validation sessions.

Alternatively, the result(s) 150 received by the orchestrator 105 include one or more intermediate results of optimization and validation of designs of the IC chip. In examples, the orchestrator 105 predicts one or more metrics at an intermediate operating frequency among the plurality of operating frequencies, by interpolating the one or more intermediate results. The orchestrator 105 identifies the one or more first cones of logic, by determining which of the plurality of cones of logic has a change in terms of at least one predicted metric for that cone of logic that exceeds a threshold value when comparing a configuration corresponding to a first operating frequency among the plurality of operating frequencies with a configuration corresponding to a second operating frequency among the plurality of operating frequencies. Similarly, the orchestrator 105 identifies the one or more second cones of logic, by determining which of the plurality of cones of logic has a change in terms of at least one predicted metric for that cone of logic that falls below the threshold value when comparing a configuration corresponding to the first operating frequency with a configuration corresponding to the second operating frequency. The orchestrator 105 sends instructions 125 including instructions to optimize and validate designs of the IC chip that are constrained by two or more operating frequencies among the plurality of operating frequencies, and instructions to re-allocate a portion of runtime, speed, or delay per cone of logic from the one or more second cones of logic to the one or more first cones of logic during each of the plurality of sequential optimization and/or validation sessions.

In some examples, the result(s) 150 further received by the orchestrator 105 further includes a first value for each of the one or more measured metrics 145 for that cone of logic from the EDA tool when optimizing and/or validating the designs of the IC chip that are constrained by the first operating frequency and a second value for each of the one or more measured metrics 145 for that cone of logic from the EDA tool when optimizing and/or validating the designs of the IC chip that are constrained by the second operating frequency, based on the re-allocated portion of runtime, speed, or delay per cone of logic. The orchestrator 105 determines, for each of the one or more first cones of logic, whether a difference between the second value and the corresponding first value for at least one measured metric among the one or more measured metrics has fallen below the threshold value. The orchestrator 105 flags either one or more third cones of logic among the one or more first cones of logic for which the difference between the second value and the corresponding first value for the at least one measured metric exceeds the threshold value and/or one or more fourth cones of logic among the one or more first cones of logic for which the difference between the second value and the corresponding first value for the at least one measured metric falls below the threshold value. In examples, the result(s) 155 that the orchestrator 105 sends to the user device(s) 110 includes updated results including at least one of the initial results, the first and second values for each cone of logic, the flagged one or more third cones of logic, and/or the flagged one or more fourth cones of logic.

In some examples, the orchestrator 105 identifies, for each of the one or more second cones of logic, one or more first factors that contribute to the change that that cone of logic undergoes in terms of the one or more measured metrics for that cone of logic falling below the threshold value, based on analysis of portions of the initial results and portions of the updated results that correspond to that cone of logic. In some instances, the one or more first factors include at least one of optimal configurations of logic components, optimization parameters, optimization patterns, validation parameters, validation patterns, or other characteristics. Alternatively or additionally, the orchestrator 105 identifies, for each of the one or more third cones of logic, one or more second factors that contribute to the difference between the second value and the corresponding first value for the at least one measured metric exceeding the threshold value based on analysis of portions of the initial results and portions of the updated results that correspond to that cone of logic. In some cases, the one or more second factors include at least one of non-optimal configurations of logic components, optimization parameters, optimization patterns, validation parameters, validation patterns, or other characteristics. Alternatively or additionally, the orchestrator 105 identifies, for each of the one or more fourth cones of logic, one or more third factors that contribute to the difference for which the second value and the corresponding first value for the at least one measured metric falls below the threshold value, based on analysis of portions of the initial results and portions of the updated results that correspond to that cone of logic. In examples, the one or more third factors include at least one of optimal configurations of logic components, optimization parameters, optimization patterns, validation parameters, validation patterns, or other characteristics. In some examples, the updated results further include a corresponding at least one of the one or more first factors, the one or more second factors, or the one or more third factors.

In other examples, the orchestrator 105 sends instructions 125 including instructions to optimize and validate designs of the IC chip that are bounded by a first value of a sweep variable, and the result(s) 150 received by the orchestrator 105 include a first value for each of one or more measured metrics from the EDA tool when optimizing and/or validating designs of the IC chip that are bounded by the first value of the sweep variable. The orchestrator 105 sends instructions 125 including instructions to optimize and validate designs of the IC chip that are bounded by a second value of the sweep variable, and the result(s) 150 received by the orchestrator 105 include a second value for each of one or more measured metrics from the EDA tool when optimizing and/or validating designs of the IC chip that are bounded by the second value of the sweep variable. The orchestrator 105 identifies the one or more first cones of logic among the plurality of cones of logic for which a difference between the second value and the corresponding first value for at least one measured metric, among the one or more measure metrics, for that cone of logic exceeds the threshold value. Similarly, the orchestrator 105 identifies the one or more second cones of logic among the plurality of cones of logic for which a difference between the second value and the corresponding first value for the at least one measured metric for that cone of logic falls below the threshold value. The orchestrator 105 sends instructions 125 including instructions to repeat optimization and validation of the designs of the IC chip that are bounded by the first value of the sweep variable, and instructions to re-allocate a portion of optimization and validation resources from the one or more second cones of logic to the one or more first cones of logic during the repeated optimization and validation. The result(s) 150 received by the orchestrator 105 include a third value for each of one or more measured metrics from the EDA tool when repeating the optimization and validation of the designs of the IC chip that are bounded by the first value of the sweep variable, with the re-allocated portion of optimization and validation resources. The orchestrator 105 sends instructions 125 including instructions to repeat optimization and validation of the designs of the IC chip that are bounded by the second value of the sweep variable, and instructions to re-allocate a portion of optimization and validation resources from the one or more second cones of logic to the one or more first cones of logic during the repeated optimization and validation. The result(s) 150 received by the orchestrator 105 include a fourth value for each of one or more measured metrics from the EDA tool when repeating the optimization and validation of the designs of the IC chip that are bounded by the second value of the sweep variable, with the re-allocated portion of optimization and validation resources. The orchestrator 105 determines, for each of the one or more first cones of logic, whether the difference between the fourth value and the corresponding third value for the at least one measured metric has fallen below the threshold value. The orchestrator 105 flags at least one of one or more third cones of logic among the one or more first cones of logic for which the difference between the fourth value and the corresponding third value for the at least one measured metric exceeds the threshold value or one or more fourth cones of logic among the one or more first cones of logic for which the difference between the fourth value and the corresponding third value for the at least one measured metric falls below the threshold value. In examples, the result(s) 155 that the orchestrator 105 sends to the user device(s) 110 includes the first, second, third, and fourth values for each cone of logic, and the flagged at least one of the one or more third cones of logic or the one or more fourth cones of logic.

In some aspects, the orchestrator 105 determines and reports per logic cone area versus operating frequency sensitivity and/or power versus operating frequency sensitivity. Starting with a baseline implementation from the EDA tool 115 at a specific operating frequency, the orchestrator 105 causes the EDA tool 115 to generate multiple versions of the design by varying the operating frequency while holding all other inputs constant, and to run an optimization and/or validation session for each operating frequency. The number of frequency points, the frequency chosen for each, and the spacing between frequency points are selectable by a chip designer, and, in some cases, are included in the input(s) 120 from the user device(s) 110 to the orchestrator 105. A typical use case includes an extremely low operating frequency value (to establish the minimum cost), multiple values below the target operating frequency, and one value slightly above the target operating frequency. The EDA tool 115 measures and reports (in result(s) 150) the area, power, and operating frequency for each cone of logic in each of the optimization and/or validation sessions. In examples, the orchestrator 105 collates the area, power, and operating frequency for each cone of logic across all the optimization and/or validation sessions, to provide the area versus operating frequency and/or power versus operating frequency curves per cone of logic. In some examples, the orchestrator 105 publishes (e.g., in result(s) 155) reports and metrics for all cones of logic in the IC chip design that chip designers can analyze to inform their next design. In examples, the orchestrator 105 generates analytics that recommend design changes to improve the operating frequency at least cost or to reduce cost at the target operating frequency. With guidance, the analytics may be used to implement design changes it recommends, to produce a more optimal version of the design at the original operating frequency or at an alternate operating frequency. In some cases, the orchestrator 105 automatically acts on its generated insights to minimize area and/or power of the IC chip design at the target operating frequency or any other desired operating frequency.

In aspects, the orchestrator 105 calculates or causes the EDA tool 115 to calculate or measure metrics on a per cone of logic level at each of a plurality of operating frequencies. The orchestrator 105 generates per logic cone area versus operating frequency and/or power versus operating frequency sensitivities. The orchestrator 105 provides insights and/or recommendations regarding how, where, and/or which cone of logic to act upon to efficiently reduce costs and/or to improve upon operating frequency at least cost. The orchestrator 105 acts on insights to automatically improve area, power, and/or operating frequency. In examples, the orchestrator 105 calculates or causes the EDA tool 115 to calculate area and power, per cone of logic, per operating frequency point. In some instances, the orchestrator 105 generates curve-fitted graphs of area versus operating frequency and/or power versus operating frequency from the generated data points. In some cases, the orchestrator 105 generates a report(s) and/or summary(ies) of cones of logic with high cost performance ratios at chosen operating frequency steps. Alternatively or additionally, the orchestrator 105 generates a report(s) and/or summary(ies) of cones of logic with high cost performance factors (e.g., exponential or linear factors) from fitted curves. In examples, the orchestrator 105 performs automatic optimization of the IC chip designs to current or new performance points by using the per logic cone cost performance ratio to determine least cost solutions.

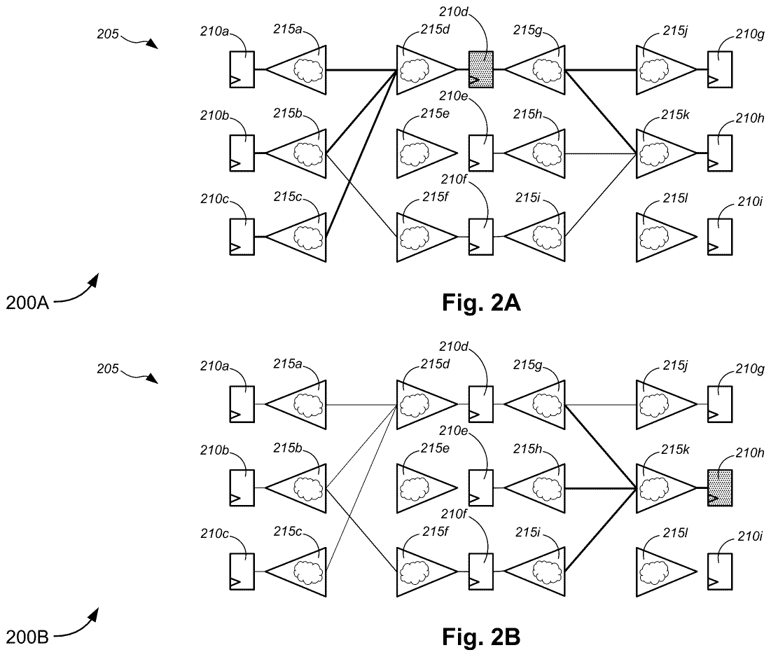

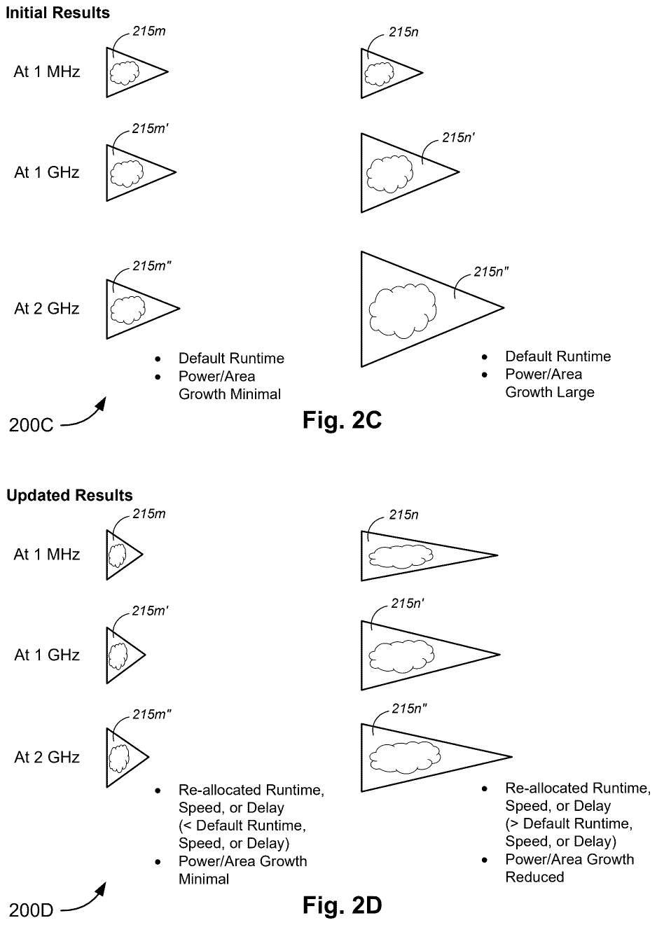

These and other functions of the system 100 (and its components) are described in greater detail below with respect to FIGS. 2A-2D, 3A-3C, 4A-4B, 5A-5C, and 6A-6C.

FIGS. 2A and 2B depict example representations 200A and 200B of relationships between cones of logic and registers that may be used when implementing orchestrated analysis and optimization of hardware designs based on logic cone analysis. FIGS. 2C and 2D depict example representations 200C and 200D of cones of logic corresponding to initial results and updated results across different operating frequencies when implementing orchestrated analysis and optimization of hardware designs based on logic cone analysis.

With reference to FIGS. 2A and 2B, at least a portion of a representation 200A or 200B of an IC chip design 205 is depicted that includes a plurality of registers 210a-210i (collectively, “registers 210”) and a plurality of cones of logic 215a-215l (collectively, “cones of logic 215”). In FIGS. 2A and 2B, some registers 210 (e.g., registers 210d-210i) include fan-in cones of logic (e.g., cones of logic 215d-215f and 215j-215l), while other registers 210 (e.g., registers 210a-210f) include fan-out cones of logic (e.g., cones of logic 215a-215c and 215g-215i). Some registers 210 (e.g., 210d-210f) include both fan-in cones of logic (e.g., cones of logic 215d-215f) and fan-out cones of logic 215g-215i).

As shown in FIG. 2A, focusing on register 210d (which is shaded for emphasis), a sequence of operations follows a path denoted by the bolded lines connecting each of registers 210a-210c to register 210d via cones of logic 215a-215d and connecting register 210d to each of registers 210g and 210h via cones of logic 215g, 215j, and 215k. In particular, fan-in cone of logic 215d receives intermediate data output from each of cones of logic 215a-215c, which each performs one of a plurality of first logical operations using input data stored in one of registers 210a-210c. Fan-in cone of logic 215d performs a second logical operation(s) based on the intermediate data, and stores a first intermediate result of the second logical operation(s) in register 210d. The fan-out cone of logic 215g performs a third logical operation(s) based on the first intermediate result, and outputs a second intermediate result(s) to each of fan-in cones of logic 215j and 215k. Fan-in cone of logic 215j performs a fourth logical operation(s) based on the second intermediate result(s), and stores a third intermediate result in register 210g. Similarly, fan-in cone of logic 215k performs a fifth logical operation(s) based at least in part on the second intermediate result(s), and stores a fourth intermediate result in register 210h. The fourth intermediate result is either output as output data or is used as input to another cone of logic.

In a similar manner, as shown in FIG. 2B, focusing on register 210h (which is shaded for emphasis), a sequence of operations follows a partial path denoted by the bolded lines connecting each of registers 210d-210f to register 210h via cones of logic 215g-215i. In particular, fan-in cone of logic 215k receives intermediate data output from each of cones of logic 215g-215i, which each performs one of a plurality of sixth logical operations using data stored in a corresponding one of registers 210d-210f. Fan-in cone of logic 215k performs a seventh logical operation based on the received intermediate data, and stores the result of the seventh logical operation in register 210h. The result of the seventh logical operation is either output as output data or is used as input to another cone of logic.

Turning to FIG. 2C, representation 200C of cones of logic corresponding to initial results is shown, where cone of logic 215m changes little in terms of power or area growth over differing operating frequencies (in this case, at 1 megahertz (MHz), at 1 gigahertz (GHz), and at 2 GHz), over a default runtime, speed, or delay, as depicted in FIG. 2C by corresponding cones of logic 215m′ and 215m″ being of similar size compared with cone of logic 215m. Here, cones of logic 215m and 215n are optimized and/or validated during a first optimization and/or validation session at the default runtime, speed, or delay, cones of logic 215m′ and 215n′ are optimized and/or validated during a second optimization and/or validation session at the default runtime, speed, or delay, and cones of logic 215m″ and 215n″ are optimized and/or validated during a third optimization and/or validation session at the default runtime, speed, or delay. This is in contrast to cone of logic 215n, which increases in terms of power or area growth with increasing operating frequencies, over the default runtime, speed, or delay, as depicted in FIG. 2C by cone of logic 215n′ (at 1 GHz operating frequency) being larger than cone of logic 215n (at 1 MHz operating frequency) and cone of logic 215n″ (at 2 GHz operating frequency) being larger than cone of logic 215n′ (at 1 GHz operating frequency).

Referring to FIG. 2D, representation 200D of cones of logic corresponding to updated results is shown, where a portion of runtime, speed, or delay for cones of logic 215m, 215m′, and 215m″ over corresponding operating frequencies 1 MHz, 1 GHz, and 2 GHz is re-allocated to cones of logic 215n, 215n′, and 215n″ during the first, second, and third optimization and/or validation sessions, respectively, such that the re-allocated portion of runtime, speed, or delay for the cones of logic 215m, 215m′, and 215m″ is less than the default runtime, speed, or delay, and the re-allocated portion of runtime, speed, or delay for the cones of logic 215n, 215n′, and 215n″ is greater than the default runtime, speed, or delay. In this manner, because power and/or area growth for the cones of logic 215m, 215m′, and 215m″ is minimal, less runtime is required to find an optimal set of logical components at each of the different operating frequencies. The portion of runtime, speed, or delay is re-allocated to optimizing and/or validating cones of logic 215n, 215n′, and 215n″ to run through more sets of logical components to enhance the optimization of the set of logical components.

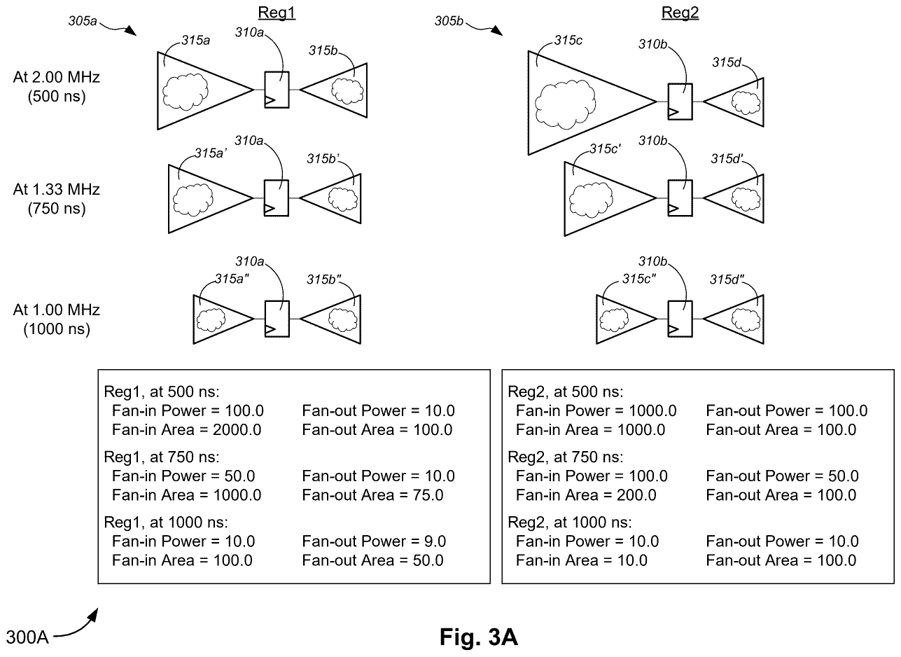

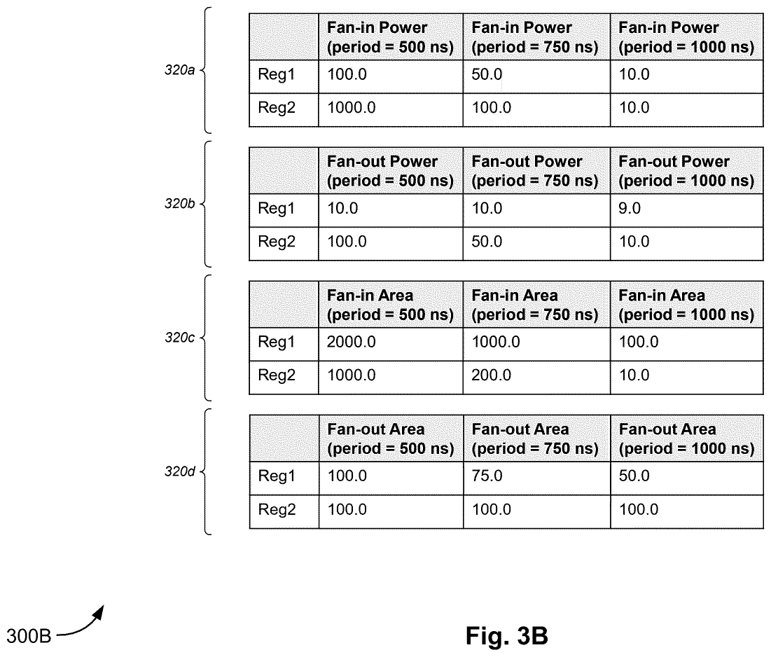

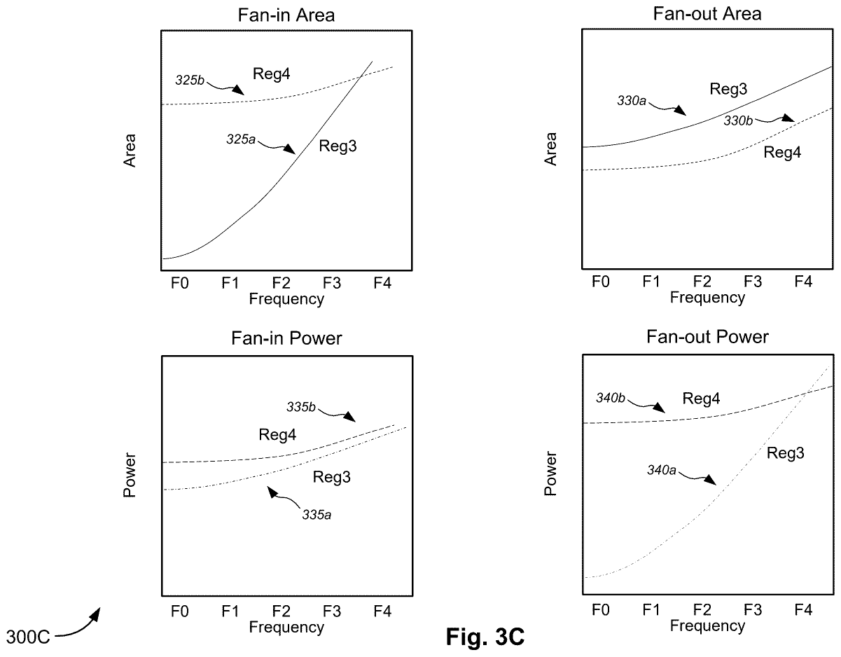

FIGS. 3A-3C depict various example results 300A-300C when implementing orchestrated analysis and optimization of hardware designs based on logic cone analysis. Example results 300A and 300B of FIGS. 3A and 3B, respectively, illustrate fan-in and fan-out power and area metrics for corresponding fan-in and fan-out cones of logic for two registers that are optimized and/or validated over different operating frequencies or periods. Example results 300C of FIG. 3C illustrates in graphical form differences in fan-in and fan-out power and area metrics for corresponding fan-in and fan-out cones of logic for two other registers that are optimized and/or validated over a plurality of different operating frequencies.

With reference to FIG. 3A, partial IC chip design 305a is depicted that includes a first register (or “Reg1”) 310a having a fan-in cone of logic 315a and a fan-out cone of logic 315b at 2.00 MHz (or with a 500 nanosecond (ns) period), a fan-in cone of logic 315a′ and a fan-out cone of logic 315b′ at 1.33 MHz (or with a 750 ns period), and a fan-in cone of logic 315a″ and a fan-out cone of logic 315b″ at 1.00 MHz (or with a 1000 ns period). At 500 ns (corresponding to 2.00 MHz), the fan-in power and the fan-in area as measured at the fan-in cone of logic 315a are 100.0 microWatt (μW) and 2000.0 square micrometer (μm²), respectively, while the fan-out power and the fan-out area as measured at the fan-out cone of logic 315b are 10.0 μW and 100.0 μm², respectively. At 750 ns (corresponding to 1.33 MHz), the fan-in power and the fan-in area as measured at the fan-in cone of logic 315a′ are 50.0 μW and 1000.0 μm², respectively, while the fan-out power and the fan-out area as measured at the fan-out cone of logic 315b′ are 10.0 μW and 75.0 μm², respectively. At 1000 ns (corresponding to 1.00 MHz), the fan-in power and the fan-in area as measured at the fan-in cone of logic 315a″ are 10.0 μW and 100.0 μm², respectively, while the fan-out power and the fan-out area as measured at the fan-out cone of logic 315b″ are 9.0 μW and 50.0 μm², respectively. While the fan-in power, the fan-in area, and the fan-out area for register Reg1 310a each decreases with increasing period (or corresponding decreases with decreasing operating frequency), the fan-out power for register Reg1 310a remains stable (or relatively unchanged) over the different periods or different operating frequencies.

Similarly, as also shown in FIG. 3A, partial IC chip design 305b is depicted that includes a second register (or “Reg2”) 310b having a fan-in cone of logic 315c and a fan-out cone of logic 315d at 2.00 MHz (or with a 500 ns period), a fan-in cone of logic 315c′ and a fan-out cone of logic 315d′ at 1.33 MHz (or with a 750 ns period), and a fan-in cone of logic 315c″ and a fan-out cone of logic 315d″ at 1.00 MHz (or with a 1000 ns period). At 500 ns (corresponding to 2.00 MHz), the fan-in power and the fan-in area as measured at the fan-in cone of logic 315c are 1000.0 μW and 1000.0 μm², respectively, while the fan-out power and the fan-out area as measured at the fan-out cone of logic 315d are 100.0 μW and 100.0 μm², respectively. At 750 ns (corresponding to 1.33 MHz), the fan-in power and the fan-in area as measured at the fan-in cone of logic 315c′ are 100.0 μW and 200.0 μm², respectively, while the fan-out power and the fan-out area as measured at the fan-out cone of logic 315d′ are 50.0 μW and 100.0 μm², respectively. At 1000 ns (corresponding to 1.00 MHz), the fan-in power and the fan-in area as measured at the fan-in cone of logic 315c″ are 10.0 μW and 10.0 μm², respectively, while the fan-out power and the fan-out area as measured at the fan-out cone of logic 315d″ are 10.0 μW and 100.0 μm², respectively. While the fan-in power, the fan-in area, and the fan-out power for register Reg2 310b each decreases with increasing period (or corresponding decreases with decreasing operating frequency), the fan-out area for register Reg2 310b remains stable (or relatively unchanged) over the different periods or different operating frequencies.

Referring to FIG. 3B, the example results 300B are depicted in Tables 320a-320d that compare the fan-in power (in Table 320a), the fan-out power (in Table 320b), the fan-in area (in Table 320c), and the fan-out power (in Table 320d) over 500, 750, and 1000 ns for register Reg1 310a and register Reg2 310b of FIG. 3A. As shown in FIG. 3B, and as described above with respect to FIG. 3A, while the fan-in power, the fan-in area, and the fan-out area for register Reg1 310a and the fan-in power, the fan-in area, and the fan-out power for register Reg2 310b each decreases with increasing period (or corresponding decreases with decreasing operating frequency), the fan-out power for register Reg1 310a and the fan-out area for register Reg2 310b each remains stable (or relatively unchanged) over the different periods or different operating frequencies.

In the example results 300A and 300B as shown in FIGS. 3A and 3B, respectively, the fan-out power for the fan-out cones of logic 315b, 315b′, and 315b″ and the fan-out area for the fan-out cones of logic 315d, 315d′, and 315d″ are relatively unchanged. As further shown in FIGS. 3A and 3B, the changes in the fan-out area for the fan-out cones of logic 315b, 315b′, and 315b″ and in the fan-out power for the fan-out cones of logic 315d, 315d′, and 315d″ are proportionally smaller compared with the larger changes in the fan-in area for fan-in cones of logic 315a, 315a′, and 315a″ and in the fan-in power and fan-in area for fan-in cones of logic 315c, 315c′, and 315c″. In a similar manner as described above with respect to FIGS. 1, 2C, and 2D, portions of the runtimes for the fan-out cones of logic 315b, 315b′, 315b″, 315d, 315d′, and 315d″ may be re-allocated to fan-in cones of logic 315a, 315a′, 315a″, 315c, 315c′, and 315c″ during subsequent optimization and/or validation sessions to provide the EDA tool more time on fan-in cones of logic 315a, 315a′, 315a″, 315c, 315c′, and 315c″ to run through other configurations of logical components to identify an optimal configuration of logical components over each of the operating frequencies or periods.

Turning to FIG. 3C, example results 300C are provided in graphical form, with fan-in area 325a for Reg3 showing a proportionally larger increase in area over a range of different operating frequencies (in this case, F0 through F4) compared with the fan-in area 325b for Reg4, which shows a proportionally smaller increase in area over the range of different operating frequencies. Fan-out areas 330a and 330b for Reg3 and Reg4, respectively, each shows a moderate increase in area over the range of different frequencies, proportionally larger than the increase in area 325b for Reg4 while proportionally smaller than the increase in area 325a for Reg3. Fan-in power 335a for Reg3 shows a slightly larger increase in power over the range of different operating frequencies compared with the fan-in power 335b for Reg4, which is similar to the proportionally smaller increase in area for the fan-in area 325b for Reg4. Fan-out power 340a for Reg3 shows a proportionally larger increase in power over the range of different operating frequencies compared with the fan-in power 340b for Reg4, with the fan-out power 340a for Reg3 being similar to the proportionally larger increase in area for the fan-in area 325a for Reg3 and the fan-out power 340b for Reg4 being similar to the proportionally smaller increase in area for the fan-in area 325b for Reg4.

In the example results 300C as shown in FIG. 3C, the fan-in area 325b and the fan-in power 335b for the fan-in cones of logic for Reg4 and the fan-out area 330b and the fan-out power 340b for the fan-out cones of logic for Reg4 are proportionally smaller in terms of changes over the range of different operating frequencies, as compared with the proportionally larger changes in area in the fan-in area 325a for the fan-in cone of logic for Reg3 and in power in the fan-out power 340a for the fan-out cone of logic for Reg3. Accordingly, the changes in the fan-out area for the fan-out cones of logic 315b, 315b′, and 315b″ and in the fan-out power for the fan-out cones of logic 315d, 315d′, and 315d″ are proportionally smaller compared with the larger changes in the fan-in area for fan-in cones of logic 315a, 315a′, and 315a″ and in the fan-in power and fan-in area for fan-in cones of logic 315c, 315c′, and 315c″. In a similar manner as described above with respect to FIGS. 1, 2C, and 2D, portions of the runtimes for the fan-out cones of logic 315b, 315b′, 315b″, 315d, 315d′, and 315d″ may be re-allocated to fan-in cones of logic 315a, 315a′, 315a″, 315c, 315c′, and 315c″ during subsequent optimization and/or validation sessions to provide the EDA tool more time to run through other configurations of logical components for fan-in cones of logic 315a, 315a′, 315a″, 315c, 315c′, and 315c″ to identify an optimal configuration of logical components over each of the operating frequencies or periods.

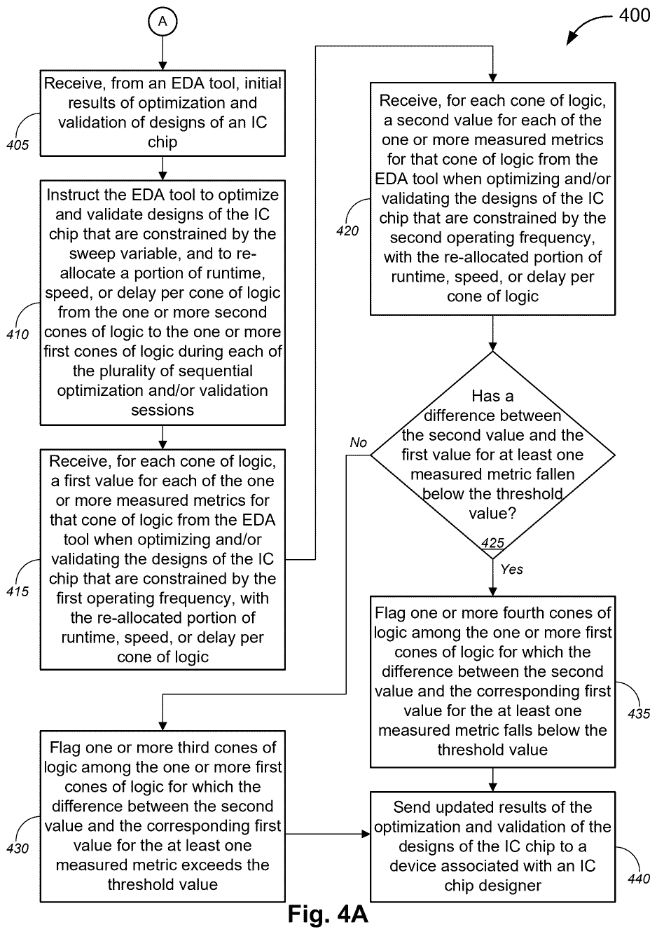

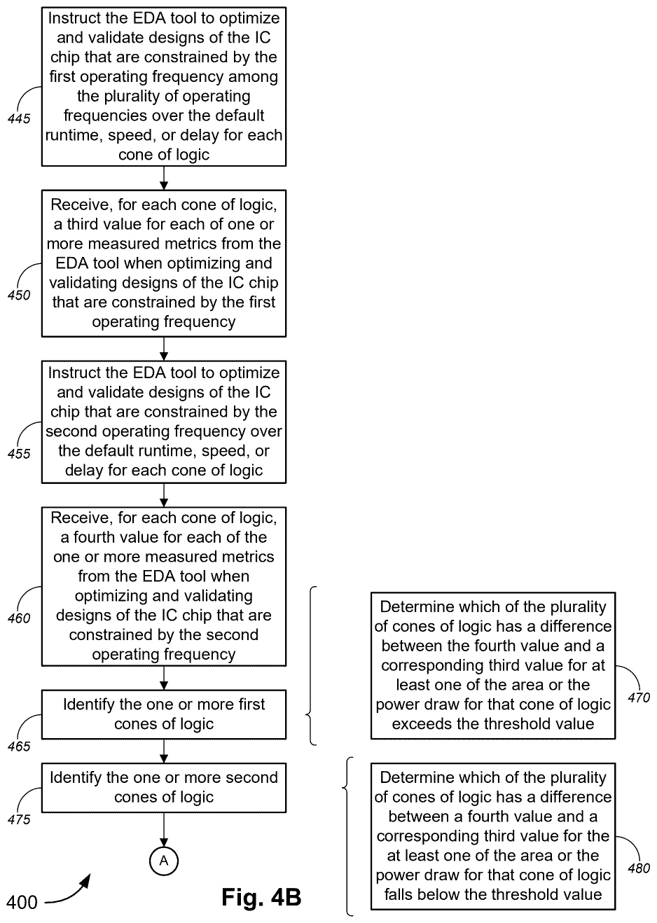

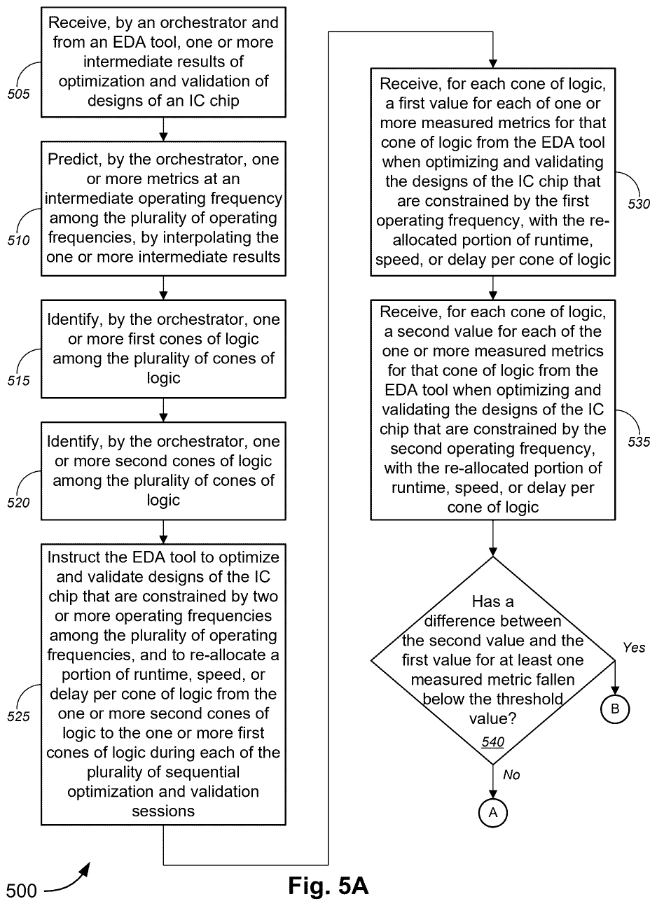

FIGS. 4A and 4B depict an example method 400 for implementing orchestrated analysis and optimization of hardware designs based on logic cone analysis. In examples, the operations of example method 400 may be performed by an orchestrator (e.g., orchestrator 105 of FIG. 1). Method 400 of FIG. 4B continues onto FIG. 4A following the circular marker denoted, “A.”

In the example of FIG. 4A, method 400, at operation 405, includes an orchestrator receiving initial results of optimization and validation of designs of an IC chip from an EDA tool (e.g., EDA tool 115 of FIG. 1). In examples, the optimization and validation utilizes a plurality of cones of logic (e.g., cones of logic 140a-140m, 215a-215l, 215m, 215m′, 215m″, 215n, 215n′, and 215n″, 315a, 315a′, 315a″, 315b, 315b′, 315b″, 315c, 315c′, 315c″, 315d, 315d′, and 315d″ of FIGS. 1, 2A-2D, and 3A), and the designs of the IC chip are constrained by a sweep variable over a default runtime, speed, or delay for each cone of logic among the plurality of cones of logic. In some cases, the sweep variable includes a plurality of operating frequencies, each being applied in one of a plurality of sequential optimization and/or validation sessions. In examples, the initial results indicate that one or more first cones of logic among the plurality of cones of logic each undergoes a change in terms of one or more measured metrics for that cone of logic that exceeds a threshold value (e.g., a change of 30, 40, 50, 60, 70, 80, 90%, or greater) when configured to operate at a first operating frequency compared with when configured to operate at a second operating frequency among the plurality of operating frequencies. In some instances, the initial results further indicate that one or more second cones of logic among the plurality of cones of logic each undergoes a change in terms of the one or more measured metrics for that cone of logic that falls below the threshold value.

At operation 410, the orchestrator instructs the EDA tool to optimize and validate designs of the IC chip that are constrained by the sweep variable, and to re-allocate a portion of runtime, speed, or delay per cone of logic from the one or more second cones of logic to the one or more first cones of logic during each of the plurality of sequential optimization and/or validation sessions. At operation 415, the orchestrator receives, for each cone of logic, a first value for each of the one or more measured metrics for that cone of logic from the EDA tool when optimizing and/or validating the designs of the IC chip that are constrained by the first operating frequency, with the re-allocated portion of runtime, speed, or delay per cone of logic. At operation 420, the orchestrator receives, for each cone of logic, a second value for each of the one or more measured metrics for that cone of logic from the EDA tool when optimizing and/or validating the designs of the IC chip that are constrained by the second operating frequency, with the re-allocated portion of runtime, speed, or delay per cone of logic.

At operation 425, the orchestrator determines, for each of the one or more first cones of logic, whether a difference between the second value and the corresponding first value for at least one measured metric among the one or more measured metrics has fallen below the threshold value. Based on a determination that the difference between the second value and the corresponding first value for at least one measured metric exceeds the threshold value, method 400 continues onto the process at operation 430. Based on a determination that the difference between the second value and the corresponding first value for at least one measured metric has fallen below the threshold value, method 400 continues onto the process at operation 435.

At operation 430, the orchestrator flags one or more third cones of logic among the one or more first cones of logic for which the difference between the second value and the corresponding first value for the at least one measured metric exceeds the threshold value. Method 400 continues onto the process at operation 440. Alternatively, at operation 435, the orchestrator flags one or more fourth cones of logic among the one or more first cones of logic for which the difference between the second value and the corresponding first value for the at least one measured metric falls below the threshold value. Method 400 continues onto the process at operation 440. At operation 440, the orchestrator sends updated results of the optimization and validation of the designs of the IC chip to a device associated with an IC chip designer. In examples, the updated results including at least one of the initial results, the first and second values for each cone of logic, the flagged one or more third cones of logic, and/or the flagged one or more fourth cones of logic.

In examples, the IC chip further includes a plurality of registers, where each set of logical components that corresponds to a logical operation receives at least one input value that is stored in corresponding at least one register among the plurality of registers and that outputs at least one output value to corresponding at least one other register among the plurality of registers. In some examples, the plurality of registers includes at least one input register, at least one output register, and a plurality of intermediate registers. In some cases, each intermediate register receives one or more input values stored in one or more first registers among the plurality of registers and outputs one or more output values for storage in one or more second registers among the plurality of registers. In some instances, the one or more first registers include one or more of the at least one input register or at least one first intermediate register among the plurality of intermediate registers. In examples, the one or more second registers include one or more of the at least one output register or at least one second intermediate register among the plurality of intermediate registers.

In some examples, the first value for each cone of logic is one of an aggregate value or an average value of a first set of intermediate values for that cone of logic obtained during the re-allocated portion of runtime, speed, or delay for that cone of logic. Similarly, the second value for each cone of logic is one of an aggregate value or an average value of a second set of intermediate values for that cone of logic obtained during the re-allocated portion of runtime, speed, or delay for that cone of logic. Each cone of logic represents a series of different design implementations of a logical operation that is sequentially optimized and/or validated in succeeding optimization and/or validation sessions among the plurality of sequential optimization and/or validation sessions by the EDA tool to identify an optimal configuration of logical components for one of a plurality of sets of logical components configured to operate at one of the plurality of operating frequencies for each of the plurality of sequential optimization and/or validation sessions.

With reference to FIG. 4B, the orchestrator instructs the EDA tool to optimize and validate designs of the IC chip that are constrained by the first operating frequency among the plurality of operating frequencies over the default runtime, speed, or delay for each cone of logic (at operation 445). The orchestrator receives, for each cone of logic, a third value for each of one or more measured metrics from the EDA tool when optimizing and validating designs of the IC chip that are constrained by the first operating frequency (at operation 450). At operation 455, the orchestrator instructs the EDA tool to optimize and validate designs of the IC chip that are constrained by the second operating frequency over the default runtime, speed, or delay for each cone of logic. At operation 460, the orchestrator receives, for each cone of logic, a fourth value for each of the one or more measured metrics from the EDA tool when optimizing and validating designs of the IC chip that are constrained by the second operating frequency. Similar to the first and second values, the third value is one of an aggregate value or an average value of a third set of intermediate values for that cone of logic obtained during the default runtime, speed, or delay for that cone of logic, while the fourth value is one of an aggregate value or an average value of a fourth set of intermediate values for that cone of logic obtained during the default runtime, speed, or delay for that cone of logic.

At operation 465, the orchestrator identifies the one or more first cones of logic, in some cases, by determining which of the plurality of cones of logic has a difference between the fourth value and a corresponding third value for at least one of the one or more measured metrics for that cone of logic exceeds the threshold value (at operation 470). Similarly, at operation 475, the orchestrator identifies the one or more second cones of logic, in some cases, by determining which of the plurality of cones of logic has a difference between the fourth value and the corresponding third value for the at least one of the one or more measured metrics that cone of logic falls below the threshold value (at operation 480). Method 400 returns to the process at operation 405 in FIG. 4A following the circular marker denoted, “A.”

In some examples, the one or more measured metrics include one or more of an area of that cone of logic or a power draw for that cone of logic. In an example, determining which of the plurality of cones of logic has a difference between the fourth value and a corresponding third value for at least one of the one or more measured metrics for that cone of logic exceeds the threshold value includes determining which of the plurality of cones of logic has a difference between the fourth value and a corresponding third value for at least one of the area or the power draw for that cone of logic exceeds the threshold value. In another example, determining which of the plurality of cones of logic has a difference between a fourth value and a corresponding third value for the at least one of the one or more measured metrics that cone of logic falls below the threshold value includes determining which of the plurality of cones of logic has a difference between a fourth value and a corresponding third value for the at least one of the area or the power draw for that cone of logic falls below the threshold value.

In examples, for each optimization and/or validation session among the plurality of sequential optimization and/or validation session, the EDA tool is caused to repeat an optimization and validation cycle for each cone of logic, until the default runtime, speed, or delay for that cone of logic has elapsed. In some examples, the optimization and validation cycle includes:
(a) optimizing and/or validating a design implementation of the logical operation for that cone of logic;
(b) obtaining an intermediate value for each of one or more measured metrics for the design implementation; and
(c) changing to another design implementation of the logical operation for that cone of logic.

In some examples, the orchestrator identifies, for each of the one or more second cones of logic, one or more first factors that contribute to the change that that cone of logic undergoes in terms of the one or more measured metrics for that cone of logic falling below the threshold value, based on analysis of portions of the initial results and portions of the updated results that correspond to that cone of logic. In some cases, the one or more first factors include at least one of optimal configurations of logic components, optimization parameters, optimization patterns, validation parameters, validation patterns, or other characteristics. Alternatively or additionally, the orchestrator identifies, for each of the one or more third cones of logic, one or more second factors that contribute to the difference between the second value and the corresponding first value for the at least one measured metric exceeding the threshold value based on analysis of portions of the initial results and portions of the updated results that correspond to that cone of logic. In some instances, the one or more second factors include at least one of non-optimal configurations of logic components, optimization parameters, optimization patterns, validation parameters, validation patterns, or other characteristics. Alternatively or additionally, the orchestrator identifies, for each of the one or more fourth cones of logic, one or more third factors that contribute to the difference for which the second value and the corresponding first value for the at least one measured metric falls below the threshold value, based on analysis of portions of the initial results and portions of the updated results that correspond to that cone of logic. In examples, the one or more third factors include at least one of optimal configurations of logic components, optimization parameters, optimization patterns, validation parameters, validation patterns, or other characteristics. In some examples, the updated results further include a corresponding at least one of the one or more first factors, the one or more second factors, and/or the one or more third factors.

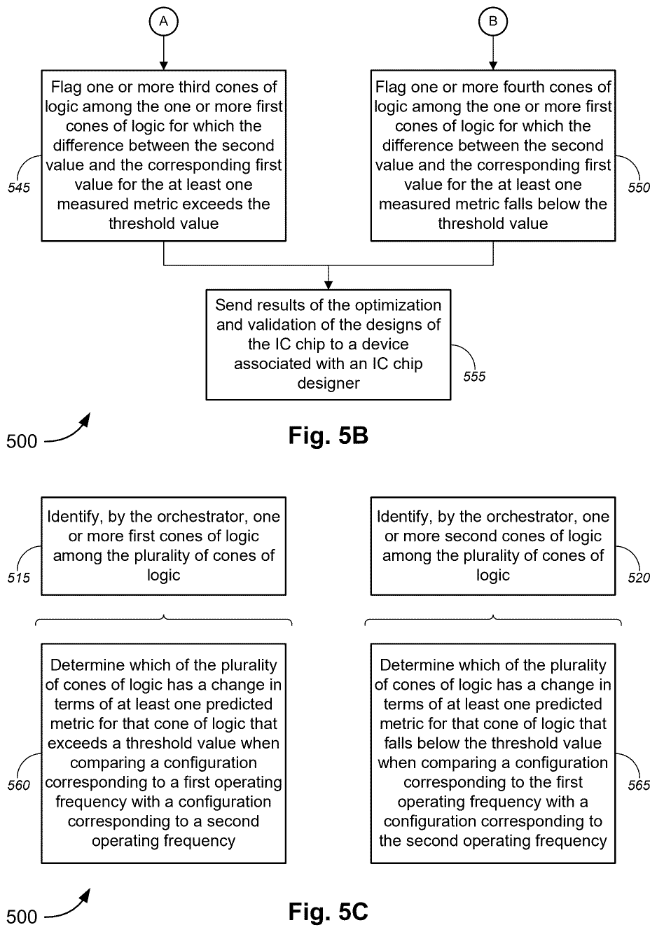

FIGS. 5A-5C depict another example method 500 for implementing orchestrated analysis and optimization of hardware designs based on logic cone analysis. In examples, the operations of example method 500 may be performed by an orchestrator (e.g., orchestrator 105 of FIG. 1). Method 500 of FIG. 5A continues onto FIG. 5B following either the circular marker denoted, “A,” or the circular marker denoted, “B.”

Referring to FIG. 5A, method 500, at operation 505, includes an orchestrator receiving one or more intermediate results of optimization and validation of designs of an IC chip from an EDA tool (e.g., EDA tool 115 of FIG. 1). In examples, the optimization and validation utilizes a plurality of cones of logic, and the designs of the IC chip are constrained by a sweep variable over a default runtime, speed, or delay for each cone of logic among the plurality of cones of logic. In some cases, the sweep variable includes one or more intermediate operating frequencies among a plurality of operating frequencies, each intermediate operating frequency being applied in one of a plurality of sequential optimization and/or validation sessions. Each cone of logic represents a series of different design implementations of a logical operation that is sequentially optimized and/or validated in succeeding optimization and/or validation sessions among the plurality of sequential optimization and/or validation sessions by the EDA tool to identify an optimal configuration of logical components for one of a plurality of sets of logical components configured to operate at one of the plurality of operating frequencies for each of the plurality of sequential optimization and/or validation sessions.

At operation 510, the orchestrator predicts one or more metrics at an intermediate operating frequency among the plurality of operating frequencies, in some cases, by interpolating the one or more intermediate results. The orchestrator identifies one or more first cones of logic among the plurality of cones of logic (at operation 515) and identifies one or more second cones of logic among the plurality of cones of logic (at operation 520). At operation 525, the orchestrator instructs the EDA tool to optimize and validate designs of the IC chip that are constrained by two or more operating frequencies among the plurality of operating frequencies, and to re-allocate a portion of runtime, speed, or delay per cone of logic from the one or more second cones of logic to the one or more first cones of logic during each of the plurality of sequential optimization and validation sessions

At operation 530, the orchestrator receives, for each cone of logic, a first value for each of one or more measured metrics for that cone of logic from the EDA tool when optimizing and validating the designs of the IC chip that are constrained by the first operating frequency, with the re-allocated portion of runtime, speed, or delay per cone of logic. At operation 535, the orchestrator receives, for each cone of logic, a second value for each of the one or more measured metrics for that cone of logic from the EDA tool when optimizing and validating the designs of the IC chip that are constrained by the second operating frequency, with the re-allocated portion of runtime, speed, or delay per cone of logic.

At operation 540, the orchestrator determines, for each of the one or more first cones of logic, whether a difference between the second value and the corresponding first value for at least one measured metric among the one or more measured metrics has fallen below a threshold value (e.g., a difference of 30, 40, 50, 60, 70, 80, 90%, or greater). Based on a determination that the difference between the second value and the corresponding first value for at least one measured metric exceeds the threshold value, method 500 continues onto the process at operation 545 in FIG. 5B following the circular marker denoted, “A.” Based on a determination that the difference between the second value and the corresponding first value for at least one measured metric has fallen below the threshold value, method 500 continues onto the process at operation 550 in FIG. 5B following the circular marker denoted, “B.”

At operation 545 in FIG. 5B (following the circular marker denoted, “A,” in FIG. 5A), method 500 includes the orchestrator flagging one or more third cones of logic among the one or more first cones of logic for which the difference between the second value and the corresponding first value for the at least one measured metric exceeds the threshold value. Method 500 continues onto the process at operation 555. Alternatively, at operation 550 in FIG. 5B (following the circular marker denoted, “B,” in FIG. 5A), method 500 includes the orchestrator flagging one or more fourth cones of logic among the one or more first cones of logic for which the difference between the second value and the corresponding first value for the at least one measured metric falls below the threshold value. Method 500 continues onto the process at operation 555. At operation 555, the orchestrator sends results of the optimization and validation of the designs of the IC chip to a device associated with an IC chip designer. In examples, the results include at least one of the one or more intermediate results, the first and second values for each cone of logic, the flagged one or more third cones of logic, and/or the flagged one or more fourth cones of logic.

In some examples, the IC chip further includes a plurality of registers. In some instances, each set of logical components that corresponds to a logical operation receives at least one input value that is stored in a corresponding at least one register among the plurality of registers and that outputs at least one output value to a corresponding at least one other register among the plurality of registers. In examples, the plurality of registers includes at least one input register, at least one output register, and a plurality of intermediate registers. In some cases, each intermediate register receives one or more input values stored in one or more first registers among the plurality of registers and outputs one or more output values for storage in one or more second registers among the plurality of registers. In an example, the one or more first registers include one or more of the at least one input register or at least one first intermediate register among the plurality of intermediate registers, while the one or more second registers include one or more of the at least one output register or at least one second intermediate register among the plurality of intermediate registers.

In examples, the one or more measured metrics and the one or more metrics each include one or more of an area of that cone of logic or a power draw for that cone of logic. In some instances, the first value for each cone of logic is one of an aggregate value or an average value of a first set of intermediate values for that cone of logic obtained during the re-allocated portion of runtime, speed, or delay for that cone of logic, while the second value for each cone of logic is one of an aggregate value or an average value of a second set of intermediate values for that cone of logic obtained during the re-allocated portion of runtime, speed, or delay for that cone of logic.

Turning to FIG. 5C, identifying the one or more first cones of logic (at operation 515) includes determining which of the plurality of cones of logic has a change in terms of at least one predicted metric for that cone of logic that exceeds a threshold value (e.g., a change of 30, 40, 50, 60, 70, 80, 90%, or greater) when comparing a configuration corresponding to a first operating frequency among the plurality of operating frequencies with a configuration corresponding to a second operating frequency among the plurality of operating frequencies (at operation 560). Similarly, identifying the one or more second cones of logic (at operation 520) includes determining which of the plurality of cones of logic has a change in terms of at least one predicted metric for that cone of logic that falls below the threshold value when comparing a configuration corresponding to the first operating frequency with a configuration corresponding to the second operating frequency (at operation 565).

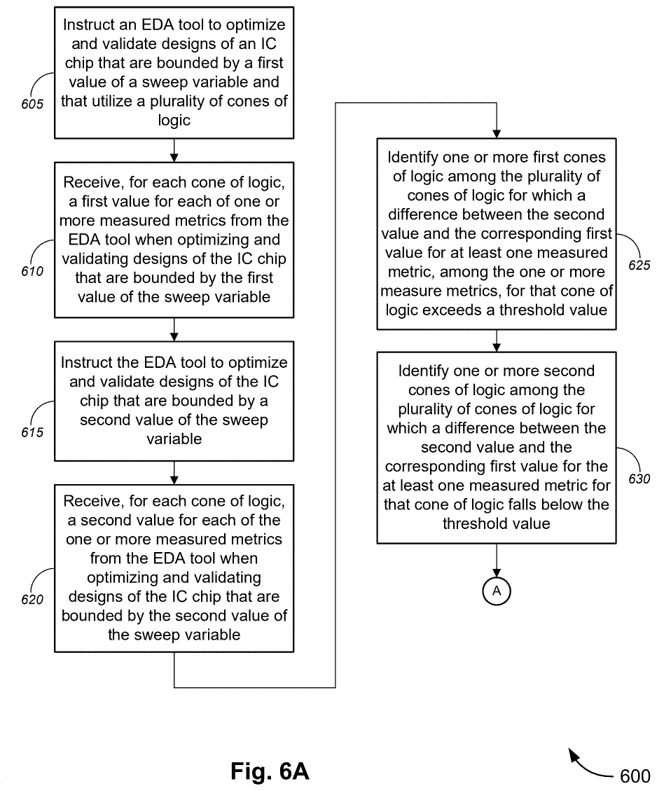

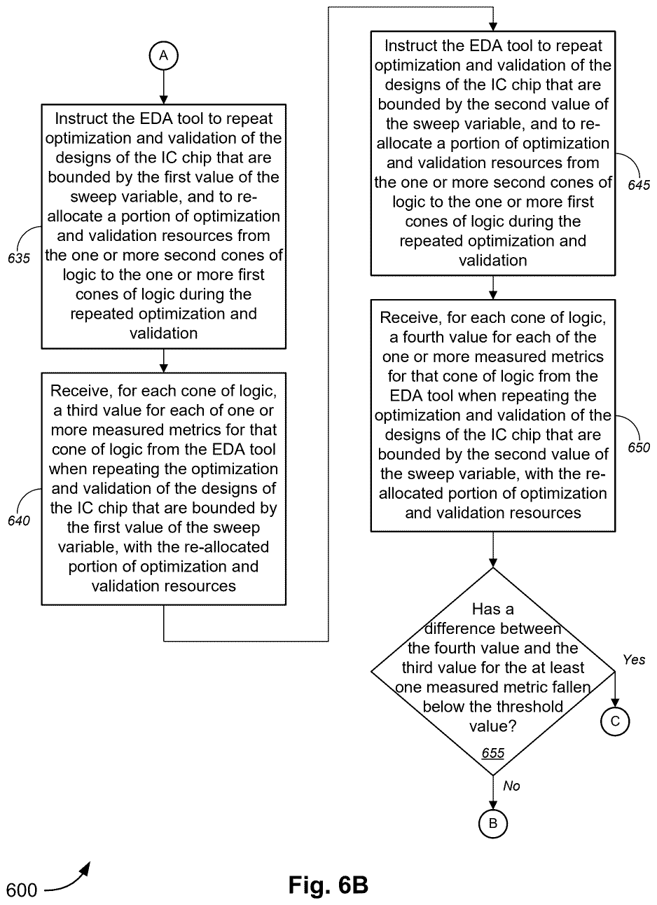

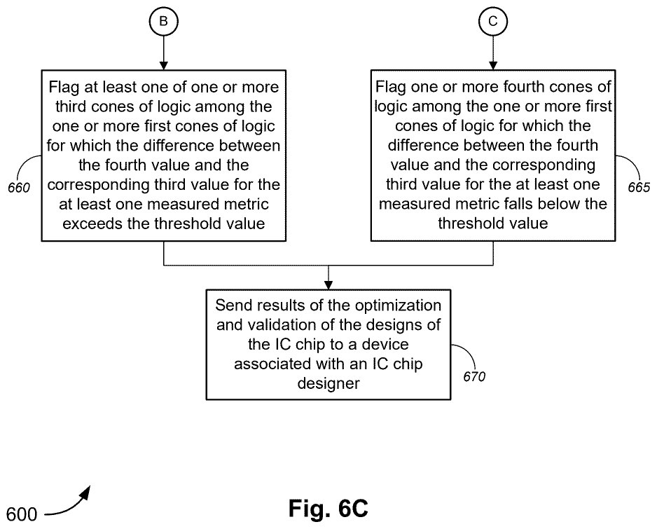

FIGS. 6A-6C depict yet another example method 600 for implementing orchestrated analysis and optimization of hardware designs based on logic cone analysis. In examples, the operations of example method 600 may be performed by an orchestrator (e.g., orchestrator 105 of FIG. 1). Method 500 of FIG. 5A continues onto FIG. 5B following either the circular marker denoted, “A.” Method 500 of FIG. 5B continues onto FIG. 5C following either the circular marker denoted, “B,” or the circular marker denoted, “C.”

With reference to FIG. 6A, method 600, at operation 605, includes an orchestrator instructing an EDA tool (e.g., EDA tool 115 of FIG. 1) to optimize and validate designs of an IC chip that are bounded by a first value of a sweep variable and that utilize a plurality of cones of logic. Each cone of logic among the plurality of cones of logic (e.g., cones of logic 140a-140m, 215a-215l, 215m, 215m′, 215m″, 215n, 215n′, and 215n″, 315a, 315a′, 315a″, 315b, 315b′, 315b″, 315c, 315c′, 315c″, 315d, 315d′, and 315d″ of FIGS. 1, 2A-2D, and 3A) representing a series of different design implementations of a corresponding logical operation to identify an optimal configuration of logical components for one of a plurality of sets of logical components configured to operate according to the first value of the sweep variable.

At operation 610, the orchestrator receives, for each cone of logic, a first value for each of one or more measured metrics from the EDA tool when optimizing and validating designs of the IC chip that are bounded by the first value of the sweep variable. At operation 615, the orchestrator instructs the EDA tool to optimize and validate designs of the IC chip that are bounded by a second value of the sweep variable. At operation 620, the orchestrator receives, for each cone of logic, a second value for each of the one or more measured metrics from the EDA tool when optimizing and validating designs of the IC chip that are bounded by the second value of the sweep variable. At operation 625, the orchestrator identifies one or more first cones of logic among the plurality of cones of logic for which a difference between the second value and the corresponding first value for at least one measured metric, among the one or more measure metrics, for that cone of logic exceeds a threshold value (e.g., a difference of 30, 40, 50, 60, 70, 80, 90%, or greater). At operation 630, the orchestrator identifies one or more second cones of logic among the plurality of cones of logic for which a difference between the second value and the corresponding first value for the at least one measured metric for that cone of logic falls below the threshold value. Method 600 continues onto the process at operation 635 in FIG. 6B following the circular marker denoted, “A.”

At operation 635 in FIG. 6B (following the circular marker denoted, “A,” in FIG. 6A), method 600 includes the orchestrator instructing the EDA tool to repeat optimization and validation of the designs of the IC chip that are bounded by the first value of the sweep variable, and to re-allocate a portion of optimization and validation resources from the one or more second cones of logic to the one or more first cones of logic during the repeated optimization and validation. At operation 640, the orchestrator receives, for each cone of logic, a third value for each of one or more measured metrics for that cone of logic from the EDA tool when repeating the optimization and validation of the designs of the IC chip that are bounded by the first value of the sweep variable, with the re-allocated portion of optimization and validation resources. At operation 645, the orchestrator instructs the EDA tool to repeat optimization and validation of the designs of the IC chip that are bounded by the second value of the sweep variable, and to re-allocate a portion of optimization and validation resources from the one or more second cones of logic to the one or more first cones of logic during the repeated optimization and validation. At operation 650, the orchestrator receives, for each cone of logic, a fourth value for each of one or more measured metrics for that cone of logic from the EDA tool when repeating the optimization and validation of the designs of the IC chip that are bounded by the second value of the sweep variable, with the re-allocated portion of optimization and validation resources.

At operation 655, the orchestrator determines, for each of the one or more first cones of logic, whether the difference between the fourth value and the corresponding third value for the at least one measured metric has fallen below the threshold value. Based on a determination that the difference between the fourth value and the corresponding third value for the at least one measured metric exceeds the threshold value, method 600 continues onto the process at operation 660 in FIG. 6C following the circular marker denoted, “B.” Based on a determination that the difference between the fourth value and the corresponding third value for the at least one measured metric has fallen below the threshold value, method 600 continues onto the process at operation 665 in FIG. 6C following the circular marker denoted, “C.”

At operation 660 in FIG. 6C (following the circular marker denoted, “B,” in FIG. 6B), method 600 includes the orchestrator flagging one or more third cones of logic among the one or more first cones of logic for which the difference between the fourth value and the corresponding third value for the at least one measured metric exceeds the threshold value. Method 600 continues onto the process at operation 670. Alternatively, at operation 665 in FIG. 6C (following the circular marker denoted, “C,” in FIG. 6B), method 600 includes the orchestrator flagging one or more fourth cones of logic among the one or more first cones of logic for which the difference between the fourth value and the corresponding third value for the at least one measured metric falls below the threshold value. Method 600 continues onto the process at operation 670. At operation 670, the orchestrator sends results of the optimization and validation of the designs of the IC chip to a device associated with an IC chip designer. In examples, the results include at least one of one or more of the first, second, third, and fourth values for each cone of logic, the flagged one or more third cones of logic, and/or the flagged one or more fourth cones of logic.

In some examples, the IC chip further includes a plurality of registers. In examples, each set of logical components that corresponds to a logical operation receives at least one input value that is stored in corresponding at least one register among the plurality of registers and that outputs at least one output value to corresponding at least one other register among the plurality of registers. In some instances, the plurality of registers includes at least one input register, at least one output register, and a plurality of intermediate registers. In some cases, each intermediate register receives one or more input values stored in one or more first registers among the plurality of registers and outputs one or more output values for storage in one or more second registers among the plurality of registers. In examples, the one or more first registers include one or more of the at least one input register or at least one first intermediate register among the plurality of intermediate registers. In some examples, the one or more second registers include one or more of the at least one output register or at least one second intermediate register among the plurality of intermediate registers.

In an example, the sweep variable is an operating frequency of the IC chip, and the one or more measured metrics as measured for each cone of logic include one or more of an area of that cone of logic, a power draw for that cone of logic, or a runtime of the EDA tool when optimizing and/or validating designs for that cone of logic. In another example, the sweep variable is a total area of the IC chip, and the one or more measured metrics as measured for each cone of logic include one or more of an inverse of an operating frequency for that cone of logic, a power draw for that cone of logic, or a runtime of the EDA tool when optimizing and/or validating designs for that cone of logic. In yet another example, the sweep variable is a total power draw of the IC chip, and the one or more measured metrics as measured for each cone of logic include one or more of an area of that cone of logic, an inverse of an operating frequency for that cone of logic, or a runtime of the EDA tool when optimizing and/or validating designs for that cone of logic. In still another example, the sweep variable is a total runtime of the EDA tool when optimizing and/or validating the designs of the IC chip, and the one or more measured metrics as measured for each cone of logic include one or more of an area of that cone of logic, a power draw for that cone of logic, or an inverse of an operating frequency for that cone of logic.

While the techniques and procedures in methods 400, 500, and 600 are depicted and/or described in a certain order for purposes of illustration, it should be appreciated that certain procedures may be reordered and/or omitted within the scope of various embodiments. Moreover, while the methods 400, 500, and 600 may be implemented by or with (and, in some cases, are described below with respect to) the systems, examples, or embodiments 100, 200A-200D, and 300A-300C of FIGS. 1, 2A-2D, and 3A-3C, respectively (or components thereof), such methods may also be implemented using any suitable hardware (or software) implementation. Similarly, while each of the systems, examples, or embodiments 100, 200A-200D, and 300A-300C of FIGS. 1, 2A-2D, and 3A-3C, respectively (or components thereof), can operate according to the methods 400, 500, and 600 (e.g., by executing instructions embodied on a computer readable medium), the systems, examples, or embodiments 100, 200A-200D, and 300A-300C of FIGS. 1, 2A-2D, and 3A-3C can each also operate according to other modes of operation and/or perform other suitable procedures.

As should be appreciated from the foregoing, the present technology provides multiple technical benefits and solutions to technical problems. For instance, optimizing and/or validating IC chip designs generally raises multiple technical problems. For example, one technical problem includes existing EDA tools typically only reporting performance in terms of operating frequency and cost metrics in terms of power consumption and/or area (or size) of IC chip portion at the design level, and only by measuring the current implementation. While useful to identify performance shortfalls, current reporting capabilities are inadequate to identify the best opportunities to improve cost. The present technology provides for implementing orchestrated analysis and optimization of hardware designs based on logic cone analysis. With the cost versus operating frequency sensitivity (i.e., the incremental cost for a unit increase in operating frequency) for each logic cone in the IC chip design, the present technology provides for meaningful and efficient improvement to the IC chip design in two ways: (1) by reducing in terms of power consumption and/or area (or size) of IC chip portion at a desired operating frequency, by enabling cones of logic to be redesigned with high cost versus operating frequency sensitivity; and/or (2) by enabling selecting of a solution among multiple solutions, which are available to improve the operating frequency, that achieves the desired operating frequency at least cost in terms of power consumption and/or area.

The present technology further enables the following: (a) calculate metrics on a per logic cone level at a single frequency; (b) generate per logic cone area versus operating frequency and/or power versus operating frequency sensitivities; (c) provide insights or recommendations regarding how, where, and/or which logic cone to act upon to efficiently reduce cost; (d) provide insights or recommendations about how, where, and/or which logic cone to act upon to improve frequency at least cost; and/or (e) act on the insights to automatically improve area, power, and/or frequency. The present technology also provides for the following aspects: (I) calculates or causes the EDA tool to calculate area and power, per cone of logic, per operating frequency point; (II) generates curve-fitted graphs of area versus operating frequency and/or power versus operating frequency from the generated data points; (III) generates a report(s) and/or summary(ies) of cones of logic with high cost performance ratios at chosen operating frequency steps; (IV) generates a report(s) and/or summary(ies) of cones of logic with high cost performance factors (e.g., exponential or linear factors) from fitted curves; and/or (V) performs automatic optimization of the IC chip designs to current or new performance points by using the per logic cone cost performance ratio to determine least cost solutions. In the manner above, the present technology provides for enhanced reliability of optimization and validation of IC chip designs, as well as improved process for designing IC chips that achieve an optimal balance between performance in terms of operating frequency and cost in terms of power consumption and area.

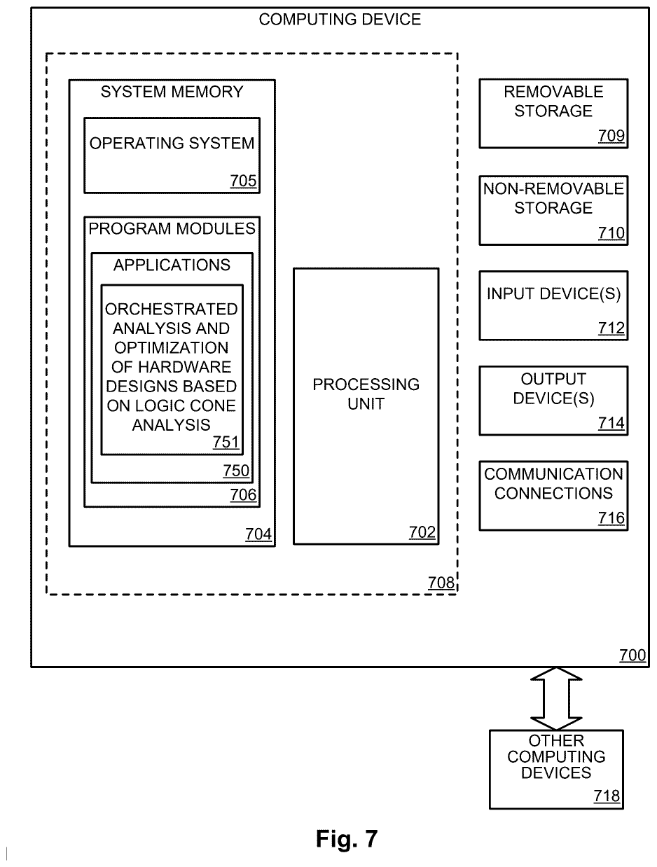

FIG. 7 depicts a block diagram illustrating physical components (i.e., hardware) of a computing device 700 with which examples of the present disclosure may be practiced. The computing device components described below may be suitable for a client device implementing the orchestrated analysis and optimization of hardware designs based on logic cone analysis, as discussed above. In a basic configuration, the computing device 700 may include at least one processing unit 702 and a system memory 704. The processing unit(s) (e.g., processors) may be referred to as a processing system. Depending on the configuration and type of computing device, the system memory 704 may include volatile storage (e.g., random access memory), non-volatile storage (e.g., read-only memory), flash memory, or any combination of such memories. The system memory 704 may include an operating system 705 and one or more program modules 706 suitable for running software applications 750, such as orchestrated analysis and optimization of hardware designs based on logic cone analysis 751, to implement one or more of the systems or methods described above.

The operating system 705, for example, may be suitable for controlling the operation of the computing device 700. Furthermore, aspects of the invention may be practiced in conjunction with a graphics library, other operating systems, or any other application program and is not limited to any particular application or system. This basic configuration is illustrated in FIG. 7 by those components within a dashed line 708. The computing device 700 may have additional features or functionalities. For example, the computing device 700 may also include additional data storage devices (which may be removable and/or non-removable), such as, for example, magnetic disks, optical disks, or tape. Such additional storage is illustrated in FIG. 7 by a removable storage device(s) 709 and a non-removable storage device(s) 710.

As stated above, a number of program modules and data files may be stored in the system memory 704. While executing on the processing unit 702, the program modules 706 may perform processes including one or more of the operations of the method(s) as illustrated in FIGS. 4A-6C, or one or more operations of the system(s) and/or apparatus(es) as described with respect to FIGS. 1-3C, or the like. Other program modules that may be used in accordance with examples of the present disclosure may include applications such as electronic mail and contacts applications, word processing applications, spreadsheet applications, database applications, slide presentation applications, drawing or computer-aided application programs, artificial intelligence (“AI”) applications and machine learning (“ML”) modules on cloud-based systems, etc.

Furthermore, examples of the present disclosure may be practiced in an electrical circuit including discrete electronic elements, packaged or integrated electronic chips containing logic gates, a circuit utilizing a microprocessor, or on a single chip containing electronic elements or microprocessors. For example, examples of the present disclosure may be practiced via a system-on-a-chip (“SOC”) where each or many of the components illustrated in FIG. 7 may be integrated onto a single integrated circuit. Such an SOC device may include one or more processing units, graphics units, communications units, system virtualization units and various application functionalities all of which may be integrated (or “burned”) onto the chip substrate as a single integrated circuit. When operating via an SOC, the functionality, described herein, with respect to generating suggested queries, may be operated via application-specific logic integrated with other components of the computing device 700 on the single integrated circuit (or chip). Examples of the present disclosure may also be practiced using other technologies capable of performing logical operations such as, for example, AND, OR, and NOT, including mechanical, optical, fluidic, and/or quantum technologies.

The computing device 700 may also have one or more input devices 712 such as a keyboard, a mouse, a pen, a sound input device, and/or a touch input device, etc. The output device(s) 714 such as a display, speakers, and/or a printer, etc. may also be included. The aforementioned devices are examples and others may be used. The computing device 700 may include one or more communication connections 716 allowing communications with other computing devices 718. Examples of suitable communication connections 716 include radio frequency (“RF”) transmitter, receiver, and/or transceiver circuitry; universal serial bus (“USB”), parallel, and/or serial ports; and/or the like.

The term “computer readable media” as used herein may include computer storage media. Computer storage media may include volatile and nonvolatile, and/or removable and non-removable, media that may be implemented in any method or technology for storage of information, such as computer readable instructions, data structures, or program modules. The system memory 704, the removable storage device 709, and the non-removable storage device 710 are all computer storage media examples (i.e., memory storage). Computer storage media may include random access memory (“RAM”), read-only memory (“ROM”), electrically erasable programmable read-only memory (“EEPROM”), flash memory or other memory technology, compact disk read-only memory (“CD-ROM”), digital versatile disks (“DVD”) or other optical storage, magnetic cassettes, magnetic tape, magnetic disk storage or other magnetic storage devices, or any other article of manufacture which can be used to store information and which can be accessed by the computing device 700. Any such computer storage media may be part of the computing device 700. Computer storage media may be non-transitory and tangible, and computer storage media do not include a carrier wave or other propagated data signal.

Communication media may be embodied by computer readable instructions, data structures, program modules, or other data in a modulated data signal, such as a carrier wave or other transport mechanism, and may include any information delivery media. The term “modulated data signal” may describe a signal that has one or more characteristics that are set or changed in such a manner as to encode information in the signal. By way of example, communication media may include wired media such as a wired network or direct-wired connection, and wireless media such as acoustic, RF, infrared, and other wireless media.

In this detailed description, wherever possible, the same reference numbers are used in the drawing and the detailed description to refer to the same or similar elements. In some instances, a sub-label is associated with a reference numeral to denote one of multiple similar components. When reference is made to a reference numeral without specification to an existing sub-label, it is intended to refer to all such multiple similar components. In some cases, for denoting a plurality of components, the suffixes “a” through “n” may be used, where n denotes any suitable non-negative integer number (unless it denotes the number 14, if there are components with reference numerals having suffixes “a” through “m” preceding the component with the reference numeral having a suffix “n”), and may be either the same or different from the suffix “n” for other components in the same or different figures. For example, for component #1 X05a-X05n, the integer value of n in X05n may be the same or different from the integer value of n in X10n for component #2 X10a-X10n, and so on. In other cases, other suffixes (e.g., s, t, u, v, w, x, y, and/or z) may similarly denote non-negative integer numbers that (together with n or other like suffixes) may be either all the same as each other, all different from each other, or some combination of same and different (e.g., one set of two or more having the same values with the others having different values, a plurality of sets of two or more having the same value with the others having different values).

Unless otherwise indicated, all numbers used herein to express quantities, dimensions, and so forth used should be understood as being modified in all instances by the term “about.” In this application, the use of the singular includes the plural unless specifically stated otherwise, and use of the terms “and” and “or” means “and/or” unless otherwise indicated. Moreover, the use of the term “including,” as well as other forms, such as “includes” and “included,” should be considered non-exclusive. Also, terms such as “element” or “component” encompass both elements and components including one unit and elements and components that include more than one unit, unless specifically stated otherwise.

In this detailed description, for the purposes of explanation, numerous specific details are set forth to provide a thorough understanding of the described embodiments. It will be apparent to one skilled in the art, however, that other embodiments of the present invention may be practiced without some of these specific details. In other instances, certain structures and devices are shown in block diagram form. While aspects of the technology may be described, modifications, adaptations, and other implementations are possible. For example, substitutions, additions, or modifications may be made to the elements illustrated in the drawings, and the methods described herein may be modified by substituting, reordering, or adding stages to the disclosed methods. Accordingly, the detailed description does not limit the technology, but instead, the proper scope of the technology is defined by the appended claims. Examples may take the form of a hardware implementation, or an entirely software implementation, or an implementation combining software and hardware aspects. Several embodiments are described herein, and while various features are ascribed to different embodiments, it should be appreciated that the features described with respect to one embodiment may be incorporated with other embodiments as well. By the same token, however, no single feature or features of any described embodiment should be considered essential to every embodiment of the invention, as other embodiments of the invention may omit such features. The detailed description is, therefore, not to be taken in a limiting sense.

Aspects of the present invention, for example, are described above with reference to block diagrams and/or operational illustrations of methods, systems, and computer program products according to aspects of the invention. The functions and/or acts noted in the blocks may occur out of the order as shown in any flowchart. For example, two blocks shown in succession may in fact be executed substantially concurrently or the blocks may sometimes be executed in the reverse order, depending upon the functionalities and/or acts involved. Further, as used herein and in the claims, the phrase “at least one of element A, element B, or element C” (or any suitable number of elements) is intended to convey any of: element A, element B, element C, elements A and B, elements A and C, elements B and C, and/or elements A, B, and C (and so on).

The description and illustration of one or more aspects provided in this application are not intended to limit or restrict the scope of the invention as claimed in any way. The aspects, examples, and details provided in this application are considered sufficient to convey possession and enable others to make and use the best mode of the claimed invention. The claimed invention should not be construed as being limited to any aspect, example, or detail provided in this application. Regardless of whether shown and described in combination or separately, the various features (both structural and methodological) are intended to be selectively rearranged, included, or omitted to produce an example or embodiment with a particular set of features. Having been provided with the description and illustration of the present application, one skilled in the art may envision variations, modifications, and alternate aspects, examples, and/or similar embodiments falling within the spirit of the broader aspects of the general inventive concept embodied in this application that do not depart from the broader scope of the claimed invention.

What is claimed is:

1. A system, comprising:
an orchestrator that executes computer executable instructions that cause the orchestrator to perform operations comprising:
receiving, from an electronic design automation (“EDA”) tool, initial results of optimization and validation of designs of an integrated circuit (“IC”) chip, the optimization and validation utilizing a plurality of cones of logic and the designs of the IC chip being constrained by a sweep variable over a default runtime, speed, or delay for each cone of logic among the plurality of cones of logic, the sweep variable including a plurality of operating frequencies, each being applied in one of a plurality of sequential optimization and validation sessions, wherein the initial results indicate that one or more first cones of logic among the plurality of cones of logic each undergoes a change in terms of one or more measured metrics for that cone of logic that exceeds a threshold value when configured to operate at a first operating frequency compared with when configured to operate at a second operating frequency among the plurality of operating frequencies, wherein the initial results further indicate that one or more second cones of logic among the plurality of cones of logic each undergoes a change in terms of the one or more measured metrics for that cone of logic that falls below the threshold value;
instructing the EDA tool to optimize and validate designs of the IC chip that are constrained by the sweep variable, and to re-allocate a portion of runtime, speed, or delay per cone of logic from the one or more second cones of logic to the one or more first cones of logic during each of the plurality of sequential optimization and validation sessions;
receiving, for each cone of logic, a first value for each of the one or more measured metrics for that cone of logic from the EDA tool when optimizing and validating the designs of the IC chip that are constrained by the first operating frequency, with the re-allocated portion of runtime, speed, or delay per cone of logic;
receiving, for each cone of logic, a second value for each of the one or more measured metrics for that cone of logic from the EDA tool when optimizing and validating the designs of the IC chip that are constrained by the second operating frequency, with the re-allocated portion of runtime, speed, or delay per cone of logic;
determining, for each of the one or more first cones of logic, whether a difference between the second value and the corresponding first value for at least one measured metric among the one or more measured metrics has fallen below the threshold value;
flagging one or more third cones of logic among the one or more first cones of logic for which the difference between the second value and the corresponding first value for the at least one measured metric exceeds the threshold value; and
sending updated results of the optimization and validation of the designs of the IC chip to a device associated with an IC chip designer, the updated results including at least one of the initial results, the first and second values for each cone of logic, or the flagged one or more third cones of logic.

2. The system of claim 1, wherein the IC chip further includes a plurality of registers, wherein each set of logical components that corresponds to a logical operation receives at least one input value that is stored in corresponding at least one register among the plurality of registers and that outputs at least one output value to corresponding at least one other register among the plurality of registers.

3. The system of claim 2, wherein the plurality of registers includes at least one input register, at least one output register, and a plurality of intermediate registers, wherein each intermediate register receives one or more input values stored in one or more first registers among the plurality of registers and outputs one or more output values for storage in one or more second registers among the plurality of registers, wherein the one or more first registers include one or more of the at least one input register or at least one first intermediate register among the plurality of intermediate registers, wherein the one or more second registers include one or more of the at least one output register or at least one second intermediate register among the plurality of intermediate registers.

4. The system of claim 1, wherein the first value for each cone of logic is one of an aggregate value or an average value of a first set of intermediate values for that cone of logic obtained during the re-allocated portion of runtime, speed, or delay for that cone of logic, wherein the second value for each cone of logic is one of an aggregate value or an average value of a second set of intermediate values for that cone of logic obtained during the re-allocated portion of runtime, speed, or delay for that cone of logic.

5. The system of claim 1, wherein each cone of logic represents a series of different design implementations of a logical operation that is sequentially optimized or validated in succeeding optimization and validation sessions among the plurality of sequential optimization and validation sessions by the EDA tool to identify an optimal configuration of logical components for one of a plurality of sets of logical components configured to operate at one of the plurality of operating frequencies for each of the plurality of sequential optimization and validation sessions.

6. The system of claim 5, wherein the operations further comprise, prior to receiving the initial results from the EDA tool:
instructing the EDA tool to optimize and validate designs of the IC chip that are constrained by the first operating frequency among the plurality of operating frequencies over the default runtime, speed, or delay for each cone of logic;
receiving, for each cone of logic, a third value for each of one or more measured metrics from the EDA tool when optimizing and validating designs of the IC chip that are constrained by the first operating frequency, the third value being one of an aggregate value or an average value of a third set of intermediate values for that cone of logic obtained during the default runtime, speed, or delay for that cone of logic;
instructing the EDA tool to optimize and validate designs of the IC chip that are constrained by the second operating frequency over the default runtime, speed, or delay for each cone of logic;
receiving, for each cone of logic, a fourth value for each of the one or more measured metrics from the EDA tool when optimizing and validating designs of the IC chip that are constrained by the second operating frequency, the fourth value being one of an aggregate value or an average value of a fourth set of intermediate values for that cone of logic obtained during the default runtime, speed, or delay for that cone of logic;
identifying the one or more first cones of logic, by determining which of the plurality of cones of logic has a difference between the fourth value and a corresponding third value for at least one of the one or more measured metrics for that cone of logic exceeds the threshold value; and
identifying the one or more second cones of logic, by determining which of the plurality of cones of logic has a difference between the fourth value and the corresponding third value for the at least one of the one or more measured metrics that cone of logic falls below the threshold value.

7. The system of claim 6, wherein the one or more measured metrics include one or more of an area of that cone of logic or a power draw for that cone of logic, wherein:
determining which of the plurality of cones of logic has a difference between the fourth value and a corresponding third value for at least one of the one or more measured metrics for that cone of logic exceeds the threshold value comprises determining which of the plurality of cones of logic has a difference between the fourth value and a corresponding third value for at least one of the area or the power draw for that cone of logic exceeds the threshold value; and
determining which of the plurality of cones of logic has a difference between a fourth value and a corresponding third value for the at least one of the one or more measured metrics that cone of logic falls below the threshold value comprises determining which of the plurality of cones of logic has a difference between a fourth value and a corresponding third value for the at least one of the area or the power draw for that cone of logic falls below the threshold value.

8. The system of claim 6, wherein, for each optimization and validation session among the plurality of sequential optimization and validation sessions, the EDA tool is caused to repeat an optimization and validation cycle for each cone of logic, until the default runtime, speed, or delay for that cone of logic has elapsed, the optimization and validation cycle comprising:
optimizing and validating a design implementation of the logical operation for that cone of logic;
obtaining an intermediate value for each of one or more measured metrics for the design implementation; and
changing to another design implementation of the logical operation for that cone of logic.

9. The system of claim 1, wherein the operations further comprise:
flagging one or more fourth cones of logic among the one or more first cones of logic for which the difference between the second value and the corresponding first value for the at least one measured metric falls below the threshold value; and
wherein the updated results further include the flagged one or more fourth cones of logic.

10. The system of claim 9, wherein the operations further comprise at least one of:
identifying, for each of the one or more second cones of logic, one or more first factors that contribute to the change that that cone of logic undergo in terms of the one or more measured metrics for that cone of logic falling below the threshold value, based on analysis of portions of the initial results and portions of the updated results that correspond to that cone of logic, wherein the one or more first factors include at least one of optimal configurations of logic components, optimization parameters, optimization patterns, validation parameters, validation patterns, or other characteristics;
identifying, for each of the one or more third cones of logic, one or more second factors that contribute to the difference between the second value and the corresponding first value for the at least one measured metric exceeding the threshold value based on analysis of portions of the initial results and portions of the updated results that correspond to that cone of logic, wherein the one or more second factors include at least one of non-optimal configurations of logic components, optimization parameters, optimization patterns, validation parameters, validation patterns, or other characteristics; or
identifying, for each of the one or more fourth cones of logic, one or more third factors that contribute to the difference for which the second value and the corresponding first value for the at least one measured metric falls below the threshold value, based on analysis of portions of the initial results and portions of the updated results that correspond to that cone of logic, wherein the one or more third factors include at least one of optimal configurations of logic components, optimization parameters, optimization patterns, validation parameters, validation patterns, or other characteristics;
wherein the updated results further include a corresponding at least one of the one or more first factors, the one or more second factors, or the one or more third factors.

11. A computer-implemented method, comprising:
receiving, by an orchestrator and from an electronic design automation (“EDA”) tool, one or more intermediate results of optimization and validation of designs of an integrated circuit (“IC”) chip, the optimization and validation utilizing a plurality of cones of logic and the designs of the IC chip being constrained by a sweep variable over a default runtime, speed, or delay for each cone of logic among the plurality of cones of logic, the sweep variable including one or more intermediate operating frequencies among a plurality of operating frequencies, each intermediate operating frequency being applied in one of a plurality of sequential optimization and validation sessions, each cone of logic representing a series of different design implementations of a logical operation that is sequentially optimized or validated in succeeding optimization and validation sessions among the plurality of sequential optimization and validation sessions by the EDA tool to identify an optimal configuration of logical components for one of a plurality of sets of logical components configured to operate at one of the plurality of operating frequencies for each of the plurality of sequential optimization and validation sessions;
predicting, by the orchestrator, one or more metrics at an intermediate operating frequency among the plurality of operating frequencies, by interpolating the one or more intermediate results;
identifying, by the orchestrator, one or more first cones of logic among the plurality of cones of logic, by determining which of the plurality of cones of logic has a change in terms of at least one predicted metric for that cone of logic that exceeds a threshold value when comparing a configuration corresponding to a first operating frequency among the plurality of operating frequencies with a configuration corresponding to a second operating frequency among the plurality of operating frequencies;
identifying, by the orchestrator, one or more second cones of logic among the plurality of cones of logic, by determining which of the plurality of cones of logic has a change in terms of at least one predicted metric for that cone of logic that falls below the threshold value when comparing a configuration corresponding to the first operating frequency with a configuration corresponding to the second operating frequency;
instructing the EDA tool to optimize and validate designs of the IC chip that are constrained by two or more operating frequencies among the plurality of operating frequencies, and to re-allocate a portion of runtime, speed, or delay per cone of logic from the one or more second cones of logic to the one or more first cones of logic during each of the plurality of sequential optimization and validation sessions;
receiving, for each cone of logic, a first value for each of one or more measured metrics for that cone of logic from the EDA tool when optimizing and validating the designs of the IC chip that are constrained by the first operating frequency, with the re-allocated portion of runtime, speed, or delay per cone of logic;
receiving, for each cone of logic, a second value for each of the one or more measured metrics for that cone of logic from the EDA tool when optimizing and validating the designs of the IC chip that are constrained by the second operating frequency, with the re-allocated portion of runtime, speed, or delay per cone of logic;
determining, for each of the one or more first cones of logic, whether a difference between the second value and the corresponding first value for at least one measured metric among the one or more measured metrics has fallen below the threshold value;
flagging one or more third cones of logic among the one or more first cones of logic for which the difference between the second value and the corresponding first value for the at least one measured metric exceeds the threshold value; and
sending results of the optimization and validation of the designs of the IC chip to a device associated with an IC chip designer, the results including at least one of the one or more intermediate results, the first and second values for each cone of logic, or the flagged one or more third cones of logic.

12. The computer-implemented method of claim 11, wherein the IC chip further includes a plurality of registers, wherein each set of logical components that corresponds to a logical operation receives at least one input value that is stored in corresponding at least one register among the plurality of registers and that outputs at least one output value to corresponding at least one other register among the plurality of registers.

13. The computer-implemented method of claim 12, wherein the plurality of registers includes at least one input register, at least one output register, and a plurality of intermediate registers, wherein each intermediate register receives one or more input values stored in one or more first registers among the plurality of registers and outputs one or more output values for storage in one or more second registers among the plurality of registers, wherein the one or more first registers include one or more of the at least one input register or at least one first intermediate register among the plurality of intermediate registers, wherein the one or more second registers include one or more of the at least one output register or at least one second intermediate register among the plurality of intermediate registers.

14. The computer-implemented method of claim 11, wherein the one or more measured metrics and the one or more metrics each include one or more of an area of that cone of logic or a power draw for that cone of logic, wherein the first value for each cone of logic is one of an aggregate value or an average value of a first set of intermediate values for that cone of logic obtained during the re-allocated portion of runtime, speed, or delay for that cone of logic, wherein the second value for each cone of logic is one of an aggregate value or an average value of a second set of intermediate values for that cone of logic obtained during the re-allocated portion of runtime, speed, or delay for that cone of logic.

15. A system, comprising:
an orchestrator that executes computer executable instructions that cause the orchestrator to perform operations comprising:
instructing an electronic design automation (“EDA”) tool to optimize and validate designs of an integrated circuit (“IC”) chip that are bounded by a first value of a sweep variable and that utilize a plurality of cones of logic, each cone of logic among the plurality of cones of logic representing a series of different design implementations of a corresponding logical operation to identify an optimal configuration of logical components for one of a plurality of sets of logical components configured to operate according to the first value of the sweep variable;
receiving, for each cone of logic, a first value for each of one or more measured metrics from the EDA tool when optimizing and validating designs of the IC chip that are bounded by the first value of the sweep variable;
instructing the EDA tool to optimize and validate designs of the IC chip that are bounded by a second value of the sweep variable;
receiving, for each cone of logic, a second value for each of the one or more measured metrics from the EDA tool when optimizing and validating designs of the IC chip that are bounded by the second value of the sweep variable;
identifying one or more first cones of logic among the plurality of cones of logic for which a difference between the second value and the corresponding first value for at least one measured metric, among the one or more measure metrics, for that cone of logic exceeds a threshold value;
identifying one or more second cones of logic among the plurality of cones of logic for which a difference between the second value and the corresponding first value for the at least one measured metric for that cone of logic falls below the threshold value;
instructing the EDA tool to repeat optimization and validation of the designs of the IC chip that are bounded by the first value of the sweep variable, and to re-allocate a portion of optimization and validation resources from the one or more second cones of logic to the one or more first cones of logic during the repeated optimization and validation;
receiving, for each cone of logic, a third value for each of one or more measured metrics from the EDA tool when repeating the optimization and validation of the designs of the IC chip that are bounded by the first value of the sweep variable, with the re-allocated portion of optimization and validation resources;
instructing the EDA tool to repeat optimization and validation of the designs of the IC chip that are bounded by the second value of the sweep variable, and to re-allocate a portion of optimization and validation resources from the one or more second cones of logic to the one or more first cones of logic during the repeated optimization and validation;
receiving, for each cone of logic, a fourth value for each of one or more measured metrics from the EDA tool when repeating the optimization and validation of the designs of the IC chip that are bounded by the second value of the sweep variable, with the re-allocated portion of optimization and validation resources;
determining, for each of the one or more first cones of logic, whether the difference between the fourth value and the corresponding third value for the at least one measured metric has fallen below the threshold value;
flagging at least one of one or more third cones of logic among the one or more first cones of logic for which the difference between the fourth value and the corresponding third value for the at least one measured metric exceeds the threshold value or one or more fourth cones of logic among the one or more first cones of logic for which the difference between the fourth value and the corresponding third value for the at least one measured metric falls below the threshold value; and
sending results of the optimization and validation of the designs of the IC chip to a device associated with an IC chip designer, the results including the first, second, third, and fourth values for each cone of logic, and the flagged at least one of the one or more third cones of logic or the one or more fourth cones of logic.

16. The system of claim 15, wherein the IC chip further includes a plurality of registers, wherein each set of logical components that corresponds to a logical operation receives at least one input value that is stored in corresponding at least one register among the plurality of registers and that outputs at least one output value to corresponding at least one other register among the plurality of registers, wherein the plurality of registers includes at least one input register, at least one output register, and a plurality of intermediate registers, wherein each intermediate register receives one or more input values stored in one or more first registers among the plurality of registers and outputs one or more output values for storage in one or more second registers among the plurality of registers, wherein the one or more first registers include one or more of the at least one input register or at least one first intermediate register among the plurality of intermediate registers, wherein the one or more second registers include one or more of the at least one output register or at least one second intermediate register among the plurality of intermediate registers.

17. The system of claim 15, wherein the sweep variable is an operating frequency of the IC chip, wherein the one or more measured metrics as measured for each cone of logic include one or more of an area of that cone of logic, a power draw for that cone of logic, or a runtime of the EDA tool when optimizing and validating designs for that cone of logic.

18. The system of claim 15, wherein the sweep variable is a total area of the IC chip, wherein the one or more measured metrics as measured for each cone of logic include one or more of an inverse of an operating frequency for that cone of logic, a power draw for that cone of logic, or a runtime of the EDA tool when optimizing and validating designs for that cone of logic.

19. The system of claim 15, wherein the sweep variable is a total power draw of the IC chip, wherein the one or more measured metrics as measured for each cone of logic include one or more of an area of that cone of logic, an inverse of an operating frequency for that cone of logic, or a runtime of the EDA tool when optimizing and validating designs for that cone of logic.

20. The system of claim 15, wherein the sweep variable is a total runtime of the EDA tool when optimizing and validating the designs of the IC chip, wherein the one or more measured metrics as measured for each cone of logic include one or more of an area of that cone of logic, a power draw for that cone of logic, or an inverse of an operating frequency for that cone of logic.
